(19) United States
(12) Patent Application Publication
(10) Pub. No.: US 2025/0221166 A1
(43) Pub. Date: Jul. 3, 2025

(54) DISPLAY DEVICE AND METHOD FOR FABRICATING THE SAME

(71) Applicant: Samsung Display Co., LTD., Yongin-si (KR)

(72) Inventors: Kyung Bae KIM, Yongin-si (KR); Yeon Kyung KIM, Yongin-si (KR); Kyeong Min PARK, Yongin-si (KR); Jin Joo HA, Yongin-si (KR)

(21) Appl. No.: 18/936,190

(22) Filed: Nov. 4, 2024

(30) Foreign Application Priority Data
Jan. 2, 2024 (KR) 10-2024-0000070

(51) Int. Cl. H10K 59/121; H10K 59/12; H10K 71/60

(52) U.S. Cl. CPC H10K 59/1213; H10K 59/1201; H10K 59/1216; H10K 71/60

(57) ABSTRACT

A display device includes a substrate including a first well region, a third well region, and a fifth well region, a first gate electrode on a first channel region of the first well region, a third gate electrode on a third channel region of the third well region, a fifth gate electrode on a fifth channel region of the fifth well region, a first gate insulating layer between the first channel region and the first gate electrode, a third gate insulating layer between the third channel region and the third gate electrode, a fifth gate insulating layer between the fifth channel region and the fifth gate electrode, wherein at least two of the first gate insulating layer, the third gate insulating layer, or the fifth gate insulating layer have thicknesses different from each other.

### CROSS-REFERENCE TO RELATED APPLICATION

The present application claims priority to and the benefit of Korean Patent Application No. 10-2024-0000070, filed on Jan. 2, 2024, in the Korean Intellectual Property Office, the entire disclosure of which is incorporated herein by reference.

### BACKGROUND

### 1. Field

Aspects of one or more embodiments of the present disclosure relate to a display device, and more particularly, to a display device capable of expressing fine grayscales and a method for fabricating the same.

### 2. Description of the Related Art

A head mounted display (HMD) is an image display device that is worn on a user's head in the form of glasses or helmets to form a focus at a close distance in front of the user's eyes. For example, the head mounted display may implement virtual reality (VR) or augmented reality (AR).

The head mounted display magnifies an image displayed on a small display device by using a plurality of lenses, and displays the magnified image. Therefore, the display device applied to the head mounted display may provide high-resolution images, for example, images with a resolution of 3000 PPI (Pixels Per Inch) or higher. To this end, an organic light emitting diode on silicon (OLEDoS), which is a high-resolution small organic light emitting display device, may be used (e.g., utilized) as the display device applied to the head mounted display. The OLEDoS is an image display device in which an organic light emitting diode (OLED) is disposed on a semiconductor wafer substrate on which a complementary metal oxide semiconductor (CMOS) is disposed.

The above information disclosed in this Background section is for enhancement of understanding of the background of the present disclosure, and therefore, it may contain information that does not constitute prior art.

### SUMMARY

Aspects of one or more embodiments of the present disclosure provide a display device capable of expressing fine grayscales and a method for fabricating the same.

According to one or more embodiments of the present disclosure, a display

device including: a substrate including a first well region, a third well region, and a fifth well region; a first source electrode and a first drain electrode in the first well region; a third source electrode and a third drain electrode in the third well region; a fifth source electrode and a fifth drain electrode in the fifth well region; a first gate electrode on a first channel region of the first well region; a third gate electrode on a third channel region of the third well region; a fifth gate electrode on a fifth channel region of the fifth well region; a first gate insulating layer between the first channel region and the first gate electrode; a third gate insulating layer between the third channel region and the third gate electrode; a fifth gate insulating layer between the fifth channel region and the fifth gate electrode; a first electrode connected to the first drain electrode; a light emitting layer on the first electrode; and a second electrode on the light emitting layer, wherein at least two of the first gate insulating layer, the third gate insulating layer, or the fifth gate insulating layer have thicknesses that are different from each other.

In one or more embodiments, a thickness of the third gate insulating layer is larger than (e.g., greater than) a thickness of the fifth gate insulating layer and smaller than (e.g., less than) a thickness of the first gate insulating layer.

In one or more embodiments, further including: a first transistor including the first gate electrode, the first source electrode, the first drain electrode, and the first gate insulating layer; a third transistor including the third gate electrode, the third source electrode, the third drain electrode, and the third gate insulating layer; and a first capacitor including the fifth gate electrode, the fifth source electrode, the fifth drain electrode, and the fifth gate insulating layer.

In one or more embodiments, the third transistor is connected between a driving voltage line and the first source electrode of the first transistor.

In one or more embodiments, further including a second transistor connected between a data line and the first gate electrode of the first transistor.

In one or more embodiments, the second transistor includes:
a second source electrode and a second drain electrode disposed in a second well region of the substrate; a second gate electrode on a second channel region of the second well region; and a second gate insulating layer between the second channel region and the second gate electrode.

In one or more embodiments, a thickness of the second gate insulating layer is substantially the same as (e.g., substantially equal to) the thickness of the third gate insulating layer.

In one or more embodiments, further including a fourth transistor connected between an initialization voltage line and the first drain electrode of the first transistor.

In one or more embodiments, the fourth transistor includes: a fourth source electrode and a fourth drain electrode disposed in a fourth well region of the substrate; a fourth gate electrode on a fourth channel region of the fourth well region; and a fourth gate insulating layer between the fourth channel region and the fourth gate electrode.

In one or more embodiments, a thickness of the fourth gate insulating layer is substantially the same as (e.g., substantially equal to) the thickness of the third gate insulating layer.

In one or more embodiments, further including a second capacitor connected between the first gate electrode of the first transistor and the first source electrode of the first transistor.

In one or more embodiments, the second capacitor includes: a sixth source electrode and a sixth drain electrode disposed in a sixth well region of the substrate; a sixth gate electrode on a sixth channel region of the sixth well region; and a sixth gate insulating layer between the sixth channel region and the sixth gate electrode.

In one or more embodiments, a thickness of the sixth gate insulating layer is substantially the same as (e.g., substantially equal to) the thickness of the fifth gate insulating layer.

In one or more embodiments, a thickness of the sixth gate insulating layer is larger than (e.g., greater than) the thickness of the fifth gate insulating layer.

In one or more embodiments, a thickness of the sixth gate insulating layer is smaller than (e.g., less than) the thickness of the third gate insulating layer.

In one or more embodiments, in a first pixel and a second pixel adjacent to each other, the first transistor of the first pixel and the first transistor of the second pixel are adjacent to each other.

In one or more embodiments, in a first pixel and a second pixel adjacent to each other,
the first capacitor of the first pixel and the first capacitor of the second pixel are adjacent to each other.

In one or more embodiments, the first transistor is disposed at one edge of a pixel, and the first capacitor is disposed (e.g., located) at another edge of a pixel.

According to one or more embodiments of the present disclosure, a method for fabricating a display device, including: forming a first well region, a third well region, and a fifth well region on a substrate; forming a first base insulating layer on the surface (e.g., the entire surface) of the substrate including the first well region, the third well region, and the fifth well region; forming a first photoresist pattern on the first base insulating layer to cover the first well region and the third well region; selectively removing the first base insulating layer using the first photoresist pattern as a mask to form a first base insulating layer having a thickness in the fifth well region that is less than (e.g., that is smaller than) a thickness of the first base insulating layer in the first well region and the third well region; removing the first photoresist pattern; forming a second base insulating layer on the first base insulating layer; forming a second photoresist pattern on the second base insulating layer to cover the first well region; and selectively removing the second base insulating layer using the second photoresist pattern as a mask to form a base insulating layer having a first thickness in the first well region, a third thickness in the third well region, and a fifth thickness in the fifth well region, the first thickness being greater than the third thickness, and the third thickness being greater than the fifth thickness.

In one or more embodiments, further including: removing the second photoresist pattern; forming a first gate electrode on the base insulating layer to overlap the first well region, forming a third gate electrode on the base insulating layer to overlap the third well region, and disposing a fifth gate electrode on the base insulating layer to overlap the fifth well region; and performing an ion implantation process using the first gate electrode, the third gate electrode, and the fifth gate electrode as a mask to form a first low-concentration impurity region in the first well region, to form a third low-concentration impurity region in the third well region, and to form a fifth low-concentration impurity region in the fifth well region.

In one or more embodiments, further including: selectively removing the base insulating layer using the first gate electrode, the third gate electrode, and the fifth gate electrode as a mask to form a first gate insulating layer having a first thickness between the first gate electrode and the first well region, to form a third gate insulating layer having a third thickness between the third gate electrode and the third well region, and to form a fifth gate insulating layer having a fifth thickness between the fifth gate electrode and the fifth well region.

In one or more embodiments, further including: forming a first sidewall on side surfaces of the first gate insulating layer and the first gate electrode to overlap (e.g., to overlap with) the first low-concentration impurity region, forming a third sidewall on side surfaces of the third gate insulating layer and the third gate electrode to overlap the third low-concentration impurity region, and forming a fifth sidewall on side surfaces of the fifth gate insulating layer and the fifth gate electrode to overlap the fifth low-concentration impurity region; and performing a high-concentration ion implantation process using the first gate electrode, the first sidewall, the third gate electrode, the third sidewall, the fifth gate electrode, and the fifth sidewall as a mask to form a first source electrode and a first drain electrode in a part of the first low-concentration impurity region, to form a third source electrode and a third drain electrode in a part of the third low-concentration impurity region, and to form a fifth source electrode and a fifth drain electrode in a part of the fifth low-concentration impurity region.

In accordance with a display device of one or more embodiments, an operating range in a linear region of a driving transistor may be increased, thereby allowing (e.g., enabling) fine grayscale expression of the display device.

In accordance with a display device of one or more embodiments, on/off switching capability of a switching transistor may be improved.

In accordance with a display device of one or more embodiments, the capacitance of a capacitor may be increased.

The effects according to one or more embodiments of the present disclosure are not limited to those mentioned above and various other effects are included in the drawings and in the following description of the present disclosure.

### BRIEF DESCRIPTION OF THE DRAWINGS

The above and other aspects and features of the present disclosure will become more clearly understood from the following detailed description of the illustrative, non-limiting embodiments with reference to the accompanying drawings, in which:

FIG. 1 is an exploded perspective view showing a display device, according to one or more embodiments of the present disclosure;

FIG. 2 is a block diagram illustrating a display device, according to one or more embodiments of the present disclosure;

FIG. 3 is an equivalent circuit diagram of a sub-pixel, according to one or more embodiments of the present disclosure;

FIG. 4 is a circuit diagram showing the first capacitor of FIG. 3, according to one or more embodiments of the present disclosure;

FIG. 5 is a layout diagram illustrating a display panel, according to one or more embodiments of the present disclosure;

FIGS. 6 and 7 are layout diagrams illustrating the display area of FIG. 5, according to one or more embodiments of the present disclosure;

FIG. 8 is a cross-sectional view, taken along line II-II′ of FIG. 6, and illustrating a display panel, according to one or more embodiments of the present disclosure;

FIG. 9 is a layout diagram showing the display area of FIG. 5, according to one or more embodiments of the present disclosure;

FIG. 10 is a cross-sectional view, taken along line X-X′ of FIG. 9, showing a display panel, according to one or more embodiments of the present disclosure;

FIGS. 11 to 23 are process cross-sectional views illustrating a method for fabricating a display device, according to one or more embodiments of the present disclosure;

FIG. 24 is a perspective view illustrating a head mounted display, according to one or more embodiments of the present disclosure;

FIG. 25 is an exploded perspective view illustrating the head mounted display of FIG. 24, according to one or more embodiments of the present disclosure; and

FIG. 26 is a perspective view illustrating a head mounted display, according to one or more embodiments of the present disclosure.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the present disclosure thorough and for fully conveying the scope of the present disclosure to those skilled in the art.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

The terminology used herein is intended to describe specific embodiments and is not intended to limit the present disclosure. It will be understood that the terms “comprise,” “include,” or “have” as used herein specify the presence of stated elements, but do not preclude the presence or addition of one or more other elements. The expression “at least one of X, Y, and Z,” “at least one of X, Y, or Z” and “at least one selected from the group consisting of X, Y, and Z” may be interpreted as one X, one Y, one Z, or any combination of two or more of X, Y, and Z (e.g., XYZ, XYY, YZ, ZZ, etc.). The terms “or” and “and/or” as used herein include any combination of one or more of the elements.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Spatially relative terms such as “below,” “above,” etc. may be used for descriptive purposes, thereby describing the relationship between one element or feature and another element(s) or feature(s) as illustrated in the drawings. Spatially relative terms are intended to include different directions in use, operation, and/or manufacture, in addition to the directions depicted in the drawings. For example, when the device illustrated in the figures is turned over, elements depicted as being located “below” other elements or features are located “above” the other elements or features. Accordingly, in some embodiments, the term “below” may include both up and down directions. In some embodiments, the device may be oriented in other directions (e.g., rotated by 90 degrees or in other orientations), and thus, the spatially relative terms as used herein should be interpreted accordingly.

Various embodiments are described with reference to drawings that schematically illustrate non-limiting embodiments. Accordingly, it will be expected that the shapes may vary depending on, for example, tolerances and/or manufacturing techniques. Therefore, the embodiments disclosed herein should not be construed as limited to the illustrated specific shapes, but should be construed to include changes in shapes that occur, for example, as a result of manufacturing. As such, the shapes illustrated in the drawings may not depict the actual shapes of the areas of the device, and the present embodiments are not limited thereto.

When a certain embodiment may be implemented differently, a specific process order may be different from the described order. For example, two consecutively described processes may be performed at the same or substantially at the same time or may be performed in an order opposite to the described order.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, example embodiments of the present disclosure will be described in detail with reference to the accompanying drawings.

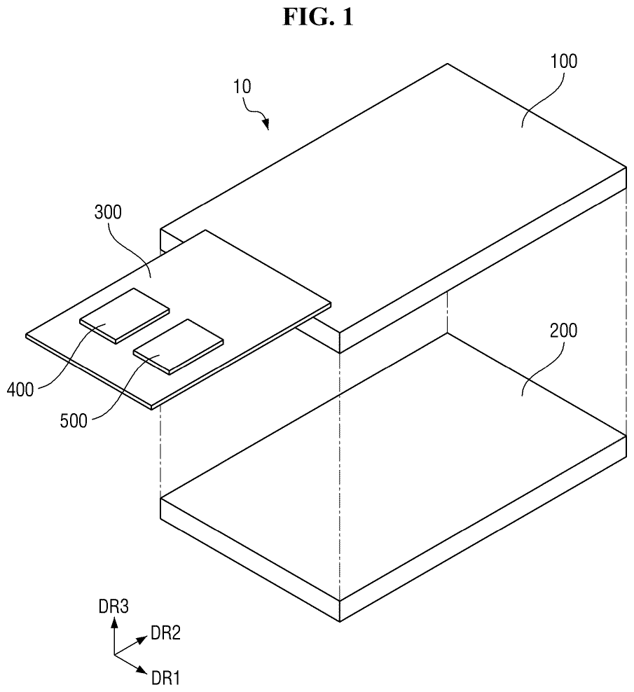

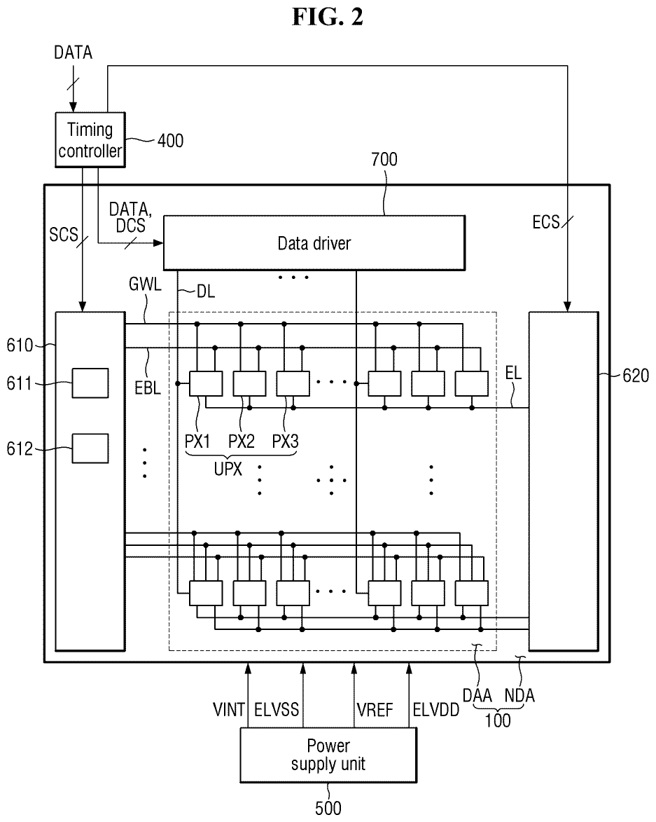

FIG. 1 is an exploded perspective view showing a display device, according to one or more embodiments of the present disclosure. FIG. 2 is a block diagram illustrating a display device, according to one or more embodiments of the present disclosure.

Referring to FIGS. 1 and 2, a display device 10 according to one or more embodiments is a device for displaying a moving image and/or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 according to one or more embodiments may be applied as a display unit of a television, a laptop, a monitor, a billboard, or an Internet-of-Things (IoT) terminal. The display device 10 according to one or more embodiments may be applied to a smart watch, a watch phone, a head mounted display (HMD) for implementing virtual reality and augmented reality, and the like.

The display device 10 according to one or more embodiments includes a display panel 100, a heat dissipation layer 200, a circuit board 300, a timing control circuit 400, and a power supply circuit 500 (e.g., a power supply unit).

The display panel 100 may have a planar shape similar to a quadrilateral shape. For example, the display panel 100 may have a planar shape similar to a quadrilateral shape, having a short side corresponding to a first direction DR1 and a long side corresponding to a second direction DR2 intersecting the first direction DR1. In the display panel 100, a corner where a short side in the first direction DR1 and a long side in the second direction DR2 meet may be right-angled or rounded with a curvature (e.g., a predetermined curvature). The planar shape of the display panel 100 is not limited to a quadrilateral shape, and may be a suitable shape similar to another polygonal shape, a circular shape, an elliptical shape, and the like. The planar shape of the display device 10 may conform to the planar shape of the display panel 100, but the present disclosure is not limited thereto.

Referring to FIG. 2, the display panel 100 may include a display area DAA for displaying an image and a non-display area NDA for not displaying an image.

The display area DAA may include a plurality of pixels PX, a plurality of scan lines GWL and EBL, a plurality of emission control lines EL, and a plurality of data lines DL.

The plurality of pixels PX may be arranged in a matrix form in the first direction DR1 and the second direction DR2. The plurality of scan lines GWL and EBL and the plurality of emission control lines EL may extend in the first direction DR1, while being disposed in the second direction DR2. The plurality of data lines DL may extend in the second direction DR2, while being disposed in (e.g., positioned along) the first direction DR1.

The plurality of scan lines GWL and EBL may include a plurality of write scan lines GWL and a plurality of bias scan lines EBL.

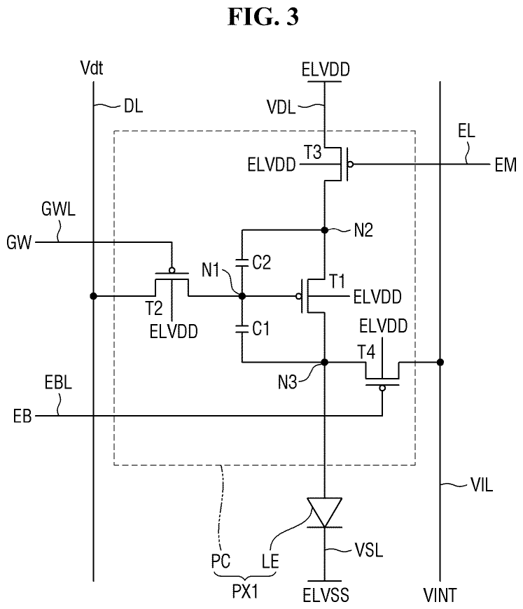

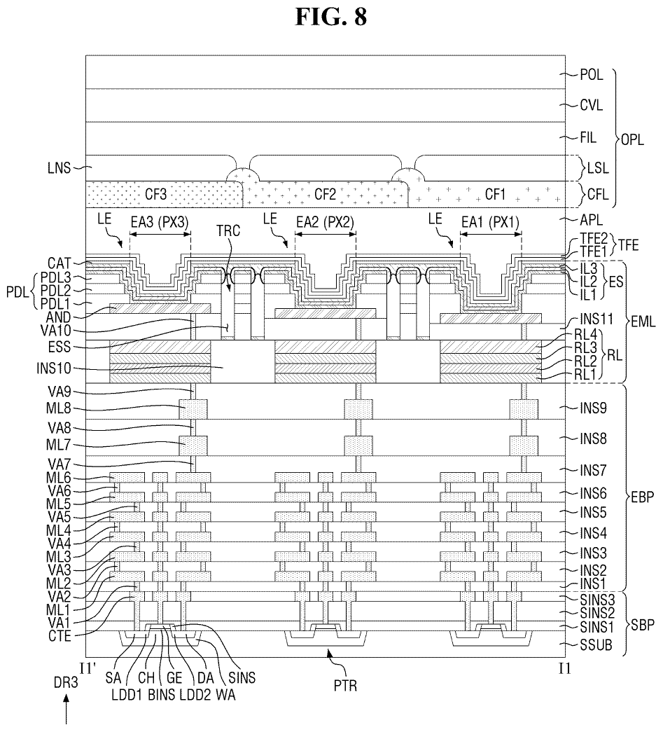

Each of a plurality of unit pixels UPX may include a plurality of pixels PX1, PX2, and PX3. The plurality of pixels PX1, PX2, and PX3 may include a plurality of pixel transistors as shown in FIG. 3, and the plurality of pixel transistors may be formed through (e.g., formed by) a semiconductor process and may be disposed on a semiconductor substrate SSUB (e.g., see FIG. 8). In some embodiments, a data driver 700 may include the plurality of pixel transistors. The pixel transistors may be formed of complementary metal oxide semiconductor (CMOS).

Each of the plurality of pixels PX1, PX2, and PX3 may be connected (e.g., coupled) to any one of the plurality of write scan lines GWL, any one of the plurality of bias scan lines EBL, any one of the plurality of emission control lines EL, and any one of the plurality of data lines DL. Each of the plurality of pixels PX1, PX2, and PX3 may receive a data voltage of the data line DL in response to a write scan signal of the write scan line GWL, and may emit light from a light emitting element LE (e.g., see FIG. 3) according to the data voltage.

The non-display area NDA may include a scan driver 610, an emission driver 620, and the data driver 700.

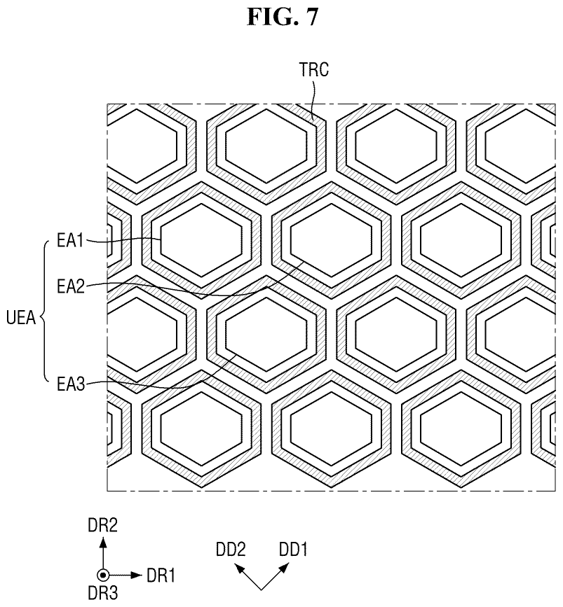

The scan driver 610 may include a plurality of scan transistors, and the emission driver 620 may include a plurality of light emitting transistors. The plurality of scan transistors and the plurality of light emitting transistors may be formed on the semiconductor substrate SSUB (e.g., see FIG. 7) through a semiconductor process. For example, the plurality of scan transistors and the plurality of light emitting transistors may be formed of CMOS (e.g., may include CMOS materials). Although it is illustrated in FIG. 2 that the scan driver 610 is disposed (e.g., located or positioned) on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 may include a write scan signal output unit 611 and a bias scan signal output unit 612. Each of the write scan signal output unit 611 and the bias scan signal output unit 612 may receive a scan timing control signal SCS from the timing control circuit 400. The write scan signal output unit 611 may generate write scan signals according to the scan timing control signal SCS of the timing control circuit 400 and output them sequentially to the write scan lines GWL. The bias scan signal output unit 612 may generate bias scan signals according to the scan timing control signal SCS and output them sequentially to bias scan lines EBL.

The emission driver 620 may receive an emission timing control signal ECS from the timing control circuit 400. The emission driver 620 may generate emission control signals in response to the emission timing control signal ECS and sequentially output them to the emission control lines EL.

The data driver 700 may include a plurality of data transistors, and the plurality of data transistors may be formed on the semiconductor substrate SSUB (e.g., see FIG. 7) through (e.g., by) a semiconductor process. For example, the plurality of data transistors may be formed of CMOS (e.g., may include CMOS materials).

The data driver 700 may receive digital video data DATA and a data timing control signal DCS from the timing control circuit 400. The data driver 700 may convert the digital video data DATA into analog data voltages according to the data timing control signal DCS and outputs the analog data voltages to the data lines DL. In one or more embodiments, the pixels PX1, PX2, and PX3 are selected by the write scan signal of the scan driver 610, and data voltages may be supplied to the selected pixels PX1, PX2, and PX3.

The heat dissipation layer 200 (see FIG. 1) may overlap the display panel 100 in a third direction DR3, which is the thickness direction of the display panel 100. The heat dissipation layer 200 may be disposed on one surface of the display panel 100, for example, on the rear surface thereof. In one or more embodiments, the heat dissipation layer 200 serves to dissipate heat generated from the display panel 100. The heat dissipation layer 200 may include a metal layer such as graphite, silver (Ag), copper (Cu), or aluminum (Al) having a relatively high thermal conductivity.

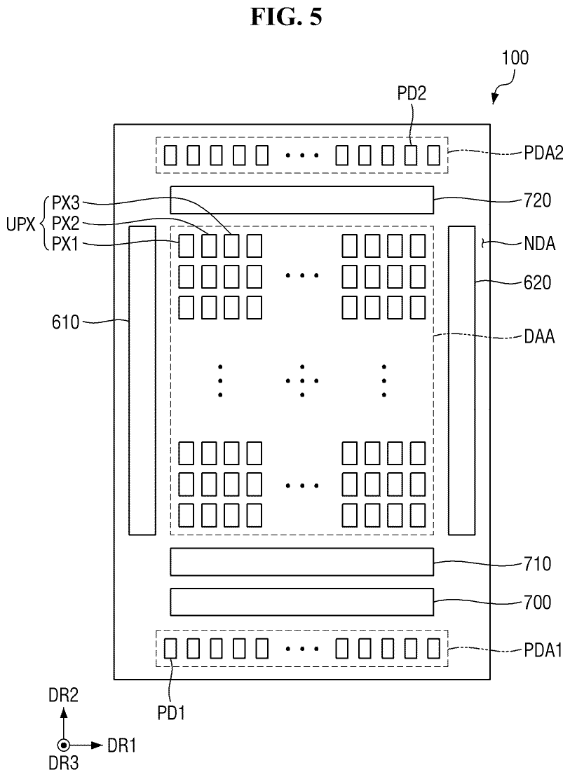

The circuit board 300 may be electrically connected to a plurality of first pads PD1 (see FIG. 5) of a first pad portion PDA1 (see FIG. 5) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent (e.g., may be foldable). In one or more embodiments, one end of the circuit board 300 may be disposed on the rear surface of the display panel 100 and/or the rear surface of the heat dissipation layer 200. One end of the circuit board 300 may be an opposite end of another end of the circuit board 300 that is connected to the plurality of first pads PD1 (see FIG. 5) of the first pad portion PDA1 (see FIG. 5) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a common voltage ELVSS, a driving voltage ELVDD, and an initialization voltage VINT and supply them to the display panel 100. The common voltage ELVSS, the driving voltage ELVDD, and the initialization voltage VINT are discussed in more detail below in conjunction with FIG. 3.

Each of the timing control circuit 400 and the power supply circuit 500 may be formed as an integrated circuit (IC) and attached to one surface of the circuit board 300. In one or more embodiments, the scan timing control signal SCS, the emission timing control signal ECS, the digital video data DATA, and the data timing control signal DCS of the timing control circuit 400 may be supplied to the display panel 100 through the circuit board 300. In one or more embodiments, the common voltage ELVSS, the driving voltage ELVDD, and the initialization voltage VINT of the power supply circuit 500 may be supplied to the display panel 100 through the circuit board 300.

In one or more embodiments, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (e.g., see FIG. 7) through a semiconductor process. For example, the plurality of timing transistors and the plurality of power transistors may be formed of CMOS (e.g., may include CMOS). Each of the timing control circuit 400 and the power supply circuit 500 may be disposed between the data driver 700 and the first pad portion PDA1 (see FIG. 5).

FIG. 3 is an equivalent circuit diagram of a sub-pixel according to one or more embodiments of the present disclosure.

As shown in FIG. 3, a first pixel PX1 may be connected to the write scan line GWL, the bias scan line EBL, the emission control line EL, an initialization voltage line VIL, the data line DL, a driving voltage line VDL, and a common voltage line VSL. Here, the common voltage line VSL may be connected to the common electrode (e.g., cathode electrode) of a light emitting element LE.

The pixel PX may include a pixel circuit PC and the light emitting element LE.

The pixel circuit PC may include a first transistor T1, a second transistor T2, a third transistor T3, a fourth transistor T4, a first capacitor C1, and a second capacitor C2.

The first transistor T1 (e.g., a driving transistor) may include a gate electrode, a source electrode, a drain electrode, and a body electrode. The first transistor T1 may control a source-drain current (hereinafter, a driving current) according to the data voltage applied to the gate electrode. The driving current (e.g., Isd) flowing through a channel region of the first transistor T1 may be proportional to the square of a difference between the threshold voltage Vth and the voltage Vsg between the source electrode and the gate electrode of the first transistor T1 (Isd=k×(Vsg−Vth)²). Here, k is a proportional coefficient determined by the structure and physical characteristics of the first transistor T1, Vsg is a source-gate voltage of the first transistor T1, and Vth is a threshold voltage of the first transistor T1. The gate electrode of the first transistor T1 may be electrically connected to a first node N1, the source electrode thereof may be electrically connected to a second node N2, the drain electrode thereof may be electrically connected to a third node N3, and the body electrode thereof may be electrically connected to the driving voltage line VDL.

The light emitting element LE may emit light by receiving the driving current Isd. The emission amount or the luminance of the light emitting element LE may be proportional to the magnitude of the driving current Isd. The light emitting element LE may be an organic light emitting diode including a first electrode, a second electrode, and an organic light emitting layer disposed between the first electrode and the second electrode. For another example, the light emitting element LE may be an inorganic light emitting element including a first electrode, a second electrode, and an inorganic semiconductor disposed between the first electrode and the second electrode. For still another example, the light emitting element LE may be a quantum dot light emitting element including a first electrode, a second electrode, and a quantum dot light emitting layer disposed between the first electrode and the second electrode. For still another example, the light emitting element LE may be a micro light emitting diode. The first electrode of the light emitting element LE may be electrically connected to the third node N3. The second electrode of the light emitting element LE may be connected to the common voltage line VSL. The second electrode of the light emitting element LE may receive a common voltage (e.g., low potential voltage) from the common voltage line VSL.

The second transistor T2 may be turned on by the write scan signal GW of the write scan line GWL to electrically connect the data line DL with the first node N1. The gate electrode of the second transistor T2 may be electrically connected to the write scan line GWL, the source electrode thereof may be electrically connected to the data line DL, the drain electrode thereof may be electrically connected to the first node N1, and the body electrode thereof may be electrically connected to the driving voltage line VDL. The data line DL may transmit a data voltage Vdt.

The third transistor T3 may be turned on by an emission control signal EM of the emission control line EL to electrically connect the driving voltage line VDL with the second node N2. The gate electrode of the third transistor T3 may be electrically connected to the emission control line EL, the source electrode thereof may be electrically connected to the driving voltage line VDL, the drain electrode thereof may be electrically connected to the second node N2, and the body electrode thereof may be electrically connected to the driving voltage line VDL.

The fourth transistor T4 may be turned on by a bias scan signal EB of the bias scan line EBL to electrically connect the third node N3 and the initialization voltage line VIL. The gate electrode of the fourth transistor T4 may be electrically connected to the bias scan line EBL, the source electrode thereof may be electrically connected to the third node N3, the drain electrode thereof may be electrically connected to the initialization voltage line VIL, and the body electrode thereof may be electrically connected to the driving voltage line VDL. In one or more embodiments, a plurality of initialization voltage lines VIL may be provided, and the plurality of initialization voltage lines VIL may be connected to each other. For example, the initialization voltage lines VIL may include a plurality of horizontal initialization voltage lines extending along the first direction DR1 and arranged in the second direction DR2 and a plurality of vertical initialization voltage lines extending along the second direction DR2 and arranged along the first direction DR1, and the horizontal initialization voltage lines and the vertical initialization voltage lines may be connected to each other.

The first capacitor C1 may be electrically connected between the first node N1 and the third node N3. For example, the first electrode of the first capacitor C1 may be electrically connected to the first node N1, and the second electrode of the first capacitor C1 may be electrically connected to the third node N3.

The second capacitor C2 may be electrically connected between the first node N1 and the second node N2. For example, the first electrode of the second capacitor C2 may be electrically connected to the first node N1, and the second electrode of the second capacitor C2 may be electrically connected to the second node N2.

The first capacitor C1 may have a capacitance larger than (e.g., greater than) that of the second capacitor C2.

When the first transistor T1 and the third transistor T3 are turned on, a driving current may be supplied to the light emitting element LE, so that the light emitting element LE may emit light.

At least one selected from among the aforementioned first to fourth transistors T1 to T4 may be a metal-oxide-semiconductor field effect transistor (MOSFET). For example, each of the first to fourth transistors T1 to T4 may be a P-type MOSFET. In one or more embodiments, each of the first to fourth transistors T1 to T4 may be an N-type MOSFET. In still another example, some of the first to fourth transistors T1 to T4 may be P-type MOSFETs, and the other transistors may be N-type MOSFETs.

Although it is illustrated in FIG. 3 that the first pixel PX1 includes the four transistors T1 to T4 and the two capacitors C1 and C2, it should be noted that the present disclosure is not limited to the example shown in FIG. 3. For example, the number of the transistors and the number of the capacitors of the first pixel PX1 are not limited to the example shown in FIG. 3.

In one or more embodiments, the equivalent circuit diagram of a second pixel PX2 and the equivalent circuit diagram of a third pixel PX3 may be substantially the same as the equivalent circuit diagram of the first pixel PX1 described in conjunction with FIG. 3. For example, in one or more embodiments, a circuit of a second pixel PX2 and a circuit of a third pixel PX3 may be substantially the same as the circuit depicted in the diagram of the first pixel PX1 described in conjunction with FIG. 3. Thus, in the present specification, description of the equivalent circuit diagram of the second pixel PX2 and the equivalent circuit diagram of the third pixel PX3 is omitted.

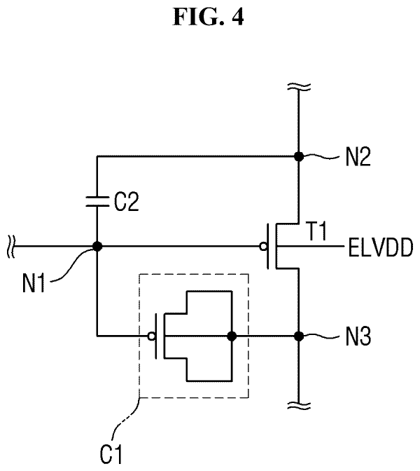

FIG. 4 is a circuit diagram showing the first capacitor of FIG. 3, according to one or more embodiments of the present disclosure.

In one or more embodiments, the first capacitor C1 may be implemented as a transistor connected between the first node N1 and the third node N3, as in the example shown in FIG. 4. In other words, the first capacitor may be (e.g., may include) a metal oxide semiconductor (MOS) capacitor. For example, the first capacitor C1 may be a P-type MOS capacitor including the gate electrode connected to the first node N1, the source electrode connected to the third node N3, the drain electrode connected to the third node N3, and the body electrode connected to the third node N3. However, the present disclosure is not limited thereto, and the first capacitor C1 may be an N-type MOS capacitor. The first capacitor C1 may also be referred to as a fifth transistor T5.

In one or more embodiments, the second capacitor C2 may be implemented as a MOS capacitor similarly to the first capacitor C1 described above. For example, the second capacitor C2 may be a P-type MOS capacitor including the gate electrode connected to the first node N1, the source electrode connected to the second node N2, the drain electrode connected to the second node N2, and the body electrode connected to the second node N2. However, the present disclosure is not limited thereto, and the second capacitor C2 may be an N-type MOS capacitor. The second capacitor C2 may also be referred to as a sixth transistor T6.

FIG. 5 is a layout diagram illustrating a display panel, according to one or more embodiments of the present disclosure.

Referring to FIG. 5, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on another side (e.g., the other side) of the display area DAA in the first direction DR1. For example, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and/or the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. For example, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a suitably rigid material or a suitably flexible printed circuit board made of a suitably flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. For example, the first distribution circuit 710 may be disposed on the lower side of the display area DAA.

The second distribution circuit 720 distributes signals applied through the

second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on another side (e.g., the other side) of the display area DAA in the second direction DR2. For example, the second distribution circuit 720 may be disposed on the upper side of the display area DAA.

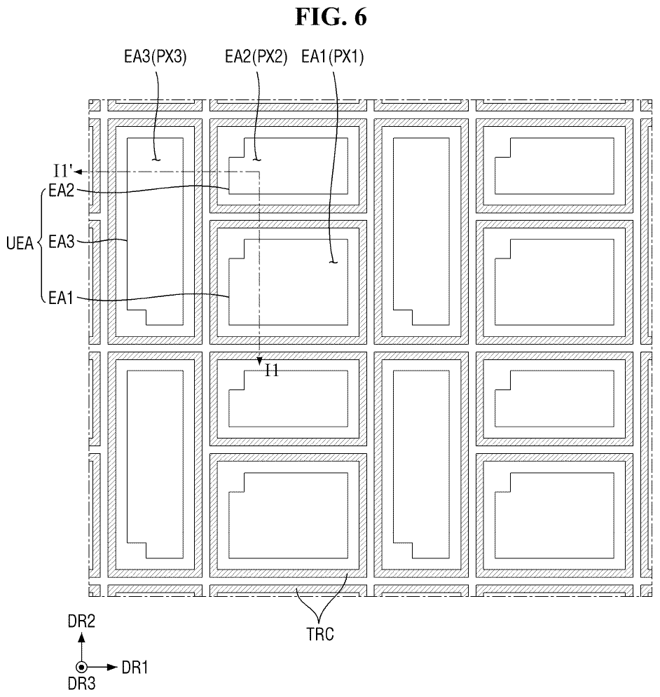

FIGS. 6 and 7 are layout diagrams illustrating the display area of FIG. 5, according to one or more embodiments of the present disclosure.

Referring to FIGS. 6 and 7, each of the plurality of unit pixels UPX includes a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area UEA, and the unit emission area UEA includes the first emission area EA1, the second emission area EA2, and the third emission area EA3 described above.

Referring to FIGS. 6 and 7, each of the plurality of pixels PX includes the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal shape, a circular shape, an elliptical shape, or an atypical shape (e.g., or another suitable shape) in a plan view.

In one or more embodiments, the maximum length of the first emission area EA1 in the first direction DR1 may be smaller than (e.g., less than) the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

In one or more embodiments, the maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than (e.g., less than) the maximum length of the second emission area EA2 in the second direction DR2.

In one or more embodiments, the maximum length of the first emission area EA1 in the first direction DR1 may be substantially equal to the maximum length of the second emission area EA2 in the first direction DR1 and greater than the maximum length of the third emission area EA3 in the first direction DR1.

In one or more embodiments, the maximum length of the first emission area EA1 in the second direction DR2 may be greater than the maximum length of the second emission area EA2 in the second direction DR2 and less than the maximum length of the third emission area EA3 in the second direction DR2. The maximum length of the second emission area EA2 in the second direction DR2 may be less than the maximum length of the third emission area EA3 in the second direction DR2. The maximum length of the first emission area EA1 in the second direction DR2 may be smaller than (e.g., less than) the maximum length of the third emission area EA3 in the second direction DR2.

In one or more embodiments, the first emission area EA1, the second emission area EA2, and the third emission area EA3 may have, in a plan view, a hexagonal shape formed of six straight lines as shown in FIGS. 6 and 7, but the present disclosure is not limited thereto. The first emission area EA1, the second emission area EA2, and the third emission area EA3 may have a polygonal shape other than a hexagon. In one or more embodiments, The first emission area EA1, the second emission area EA2, and the third emission area EA3 may have a circular shape, an elliptical shape, or an atypical shape (e.g., another suitable shape) in a plan view.

As shown in FIG. 6, in each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. In some embodiments, the second emission area EA2 and the third emission area EA3 may be adjacent to each other in the first direction DR1. The area of the first emission area EA1, the area of the second emission area EA2, and the area of the third emission area EA3 may be different from each other.

In one or more embodiments, as shown in FIG. 7, the first emission area EA1 and the second emission area EA2 may be adjacent to each other in the first direction DR1, and the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

In one or more embodiments, as depicted in FIGS. 6 and 7, each of the plurality of pixels PX may include three emission areas EA1, EA2, and EA3, but the present disclosure is not limited thereto. For example, in one or more embodiments, each of the plurality of pixels PX may include four emission areas.

In some embodiments, for example, the layout of the emission areas of the plurality of pixels PX is not limited to that illustrated in FIGS. 6 and 7. For example, the emission areas of the plurality of pixels PX may be disposed in a stripe structure in which the emission areas are arranged in the first direction DR1, an RGBG structure (e.g., a PENTILE® structure, PENTILE® being a duly registered trademark of Samsung Display Co., Ltd.) in which the emission areas are arranged in a diamond shape, or a hexagonal structure in which the emission areas having, in a plan view, a hexagonal shape are arranged side by side as shown in FIG. 7.

FIG. 8 is a cross-sectional view illustrating an example of a display panel taken along line II-II′ of FIG. 6.

Referring to FIG. 8, the display panel 100 includes a semiconductor backplane SBP, a light emitting element backplane EBP, a display element layer EML, an encapsulation layer TFE, an optical layer OPL, a cover layer CVL, and a polarizing plate POL. In one or more embodiments, the cover layer CVL and/or the polarizing plate POL may be parts of the optical layer OPL.

The semiconductor backplane SBP may include the semiconductor substrate SSUB including a plurality of pixel transistors PTR, a plurality of semiconductor insulating layers (including, e.g., a first semiconductor insulating layer SINS1 and a second semiconductor insulating layer SINS2) covering the plurality of pixel transistors PTR, and a plurality of contact terminals CTE electrically connected to corresponding ones of the plurality of pixel transistors PTR. As used herein, corresponding ones of components may refer to one or more of the components. The plurality of pixel transistors PTR may be (e.g., may include) the first to fourth transistors T1 to T4 described with reference to FIG. 3.

The semiconductor substrate SSUB may be (e.g., may include) a silicon substrate, a germanium substrate, or a silicon-germanium substrate. The semiconductor substrate SSUB may be (e.g., may include) a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. In one or more embodiments, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on (e.g., at) the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap (e.g., overlap with) the well region WA in the third direction DR3. The channel region CH may overlap the gate electrode GE in the third direction DR3. The source region SA may be disposed on one side of the gate electrode GE, and the drain region DA may be disposed on another side (e.g., the other side) of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot-carrier phenomena that might be caused by a short channel may be prevented.

The first semiconductor insulating layer SINS1 may be disposed on the semiconductor substrate SSUB. The first semiconductor insulating layer SINS1 may be formed of silicon carbonitride (SiCN) or a silicon oxide (SiOx)-based inorganic layer, but the present disclosure is not limited thereto.

The second semiconductor insulating layer SINS2 may be disposed on the first semiconductor insulating layer SINS1. The second semiconductor insulating layer SINS2 may be formed of (e.g., may include) a silicon oxide (SiOx)-based inorganic layer, but the present disclosure is not limited thereto.

The plurality of contact terminals CTE may be disposed on the second semiconductor insulating layer SINS2. Each of the plurality of contact terminals CTE may be connected to a corresponding one of the gate electrode GE, the source region SA, or the drain region DA of corresponding ones of the pixel transistors PTR through holes penetrating the first semiconductor insulating layer SINS1 and the second semiconductor insulating layer SINS2. The plurality of contact terminals CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating layer SINS3 may be disposed on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the present disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating layers INS1 to INS9. In some embodiments, for example, the light emitting element backplane EBP includes a plurality of insulating layers INS1 to INS11 disposed between the first to eighth conductive layers ML1 to ML8.

The first to eighth conductive layers ML1 to ML8 may serve to connect the plurality of contact terminals CTE exposed from the semiconductor backplane SBP to thereby implement the circuit of the first pixel PX1 shown in FIG. 3. For example, the first to sixth transistors T1 to T6 may be formed on the semiconductor backplane SBP, and the connection of the first to sixth transistors T1 to T6 (e.g., including the first and second capacitors C1 and C2) may be accomplished through the first to eighth conductive layers ML1 to ML8. In one or more embodiments, for example, the connection between the drain region corresponding to the drain electrode of the fourth transistor T4, the source region corresponding to the source electrode of the fifth transistor T5, and the first electrode of the light emitting element LE may also be accomplished through the first to eighth conductive layers ML1 to ML8. As used herein, and depending on the context, a conductive layer may refer to a plurality of conductive components located at a same layer or may refer to one conductive component from among the plurality of conductive components located at the same layer. As used herein, and depending on the context, a via may refer to a plurality of vias located at a same layer or may refer to one via from among the plurality of vias located at the same layer.

A first insulating layer INS1 may be disposed on the semiconductor backplane SBP. Each of first vias VA1 may penetrate the first insulating layer INS1 to be connected to a corresponding contact terminal CTE exposed from the semiconductor backplane SBP. Each of first conductive layers ML1 may be disposed on the first insulating layer INS1, and may be connected to a corresponding first via VA1.

A second insulating layer INS2 may be disposed on the first insulating layer INS1 and the first conductive layers ML1. Each of second vias VA2 may penetrate the second insulating layer INS2 and be connected to the corresponding exposed first conductive layer ML1. Each of second conductive layers ML2 may be disposed on the second insulating layer INS2, and may be connected to corresponding ones of the second vias VA2.

A third insulating layer INS3 may be disposed on the second insulating layer INS2 and the second conductive layers ML2. Each of third vias VA3 may penetrate the third insulating layer INS3 and be connected to corresponding ones of the exposed second conductive layers ML2. Each of third conductive layers ML3 may be disposed on the third insulating layer INS3 and may be connected to corresponding ones of the third vias VA3.

A fourth insulating layer INS4 may be disposed on the third insulating layer INS3 and the third conductive layers ML3. Each of fourth vias VA4 may penetrate the fourth insulating layer INS4 and be connected to corresponding ones of the exposed third conductive layers ML3. Each of fourth conductive layers ML4 may be disposed on the fourth insulating layer INS4 and may be connected to corresponding ones of the fourth vias VA4.

A fifth insulating layer INS5 may be disposed on the fourth insulating layer INS4 and the fourth conductive layers ML4. Each of fifth vias VA5 may penetrate the fifth insulating layer INS5 and be connected to corresponding ones of the exposed fourth conductive layers ML4. Each of fifth conductive layers ML5 may be disposed on the fifth insulating layer INS5 and may be connected to corresponding ones of the fifth vias VA5.

A sixth insulating layer INS6 may be disposed on the fifth insulating layer INS5 and the fifth conductive layers ML5. Each of sixth vias VA6 may penetrate the sixth insulating layer INS6 and be connected to corresponding ones of the exposed fifth conductive layers ML5. Each of sixth conductive layers ML6 may be disposed on the sixth insulating layer INS6 and may be connected to corresponding ones of the sixth vias VA6.

A seventh insulating layer INS7 may be disposed on the sixth insulating layer INS6 and the sixth conductive layers ML6. Each of seventh vias VA7 may penetrate the seventh insulating layer INS7 and be connected to corresponding ones of the exposed sixth conductive layers ML6. Each of seventh conductive layers ML7 may be disposed on the seventh insulating layer INS7 and may be connected to corresponding ones of the seventh vias VA7.

An eighth insulating layer INS8 may be disposed on the seventh insulating layer INS7 and the seventh conductive layers ML7. Each of eighth vias VA8 may penetrate the eighth insulating layer INS8 and be connected to corresponding ones of the exposed seventh conductive layers ML7. Each of eighth conductive layers ML8 may be disposed on the eighth insulating layer INS8 and may be connected to corresponding ones of the eighth vias VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1 to VA8 may be made of substantially the same material. The first to eighth insulating layers INS1 to INS8 may be formed of a silicon oxide (SiOx)-based inorganic layer, but the present disclosure is not limited thereto.

The thicknesses (e.g., in the third direction DR3) of the first conductive layer ML1, the second conductive layer ML2, the third conductive layer ML3, the fourth conductive layer ML4, the fifth conductive layer ML5, and the sixth conductive layer ML6 may be larger than (e.g., greater than) the thicknesses of the first vias VA1, the second vias VA2, the third vias VA3, the fourth vias VA4, the fifth vias VA5, and the sixth vias VA6, respectively. The thickness of each of the second conductive layer ML2, the third conductive layer ML3, the fourth conductive layer ML4, the fifth conductive layer ML5, and the sixth conductive layer ML6 may be larger than (e.g., greater than) the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Angstrom (Å); the thickness of each of the second conductive layer ML2, the third conductive layer ML3, the fourth conductive layer ML4, the fifth conductive layer ML5, and the sixth conductive layer ML6 may be approximately 1440 Å; and the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be larger than (e.g., greater than) the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than (e.g., greater than) the thickness of the seventh via VA7 and the thickness of the eighth via VA8, respectively. The thickness of each of the seventh via VA7 and the eighth via VA8 may be larger than (e.g., greater than) the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating layer INS9 may be disposed on the eighth insulating layer INS8 and the eighth conductive layer ML8. The ninth insulating layer INS9 may be formed of a silicon oxide (SiOx)-based inorganic layer, but the present disclosure is not limited thereto.

Each of the ninth vias VA9 may penetrate the ninth insulating layer INS9 and be connected to corresponding ones of the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the ninth via VA9 may be approximately 16500 Å.

The display element layer EML may be disposed on the light emitting element backplane EBP. The display element layer EML may include the light emitting elements LE (e.g., see FIG. 3), each including a reflective electrode layer RL, tenth and eleventh insulating layers INS10 and INS11, a tenth via VA10, a first electrode AND, a light emitting stack ES, a second electrode CAT, a pixel defining layer PDL, and a plurality of trenches TRC.

The reflective electrode layer RL may be disposed on the ninth insulating layer INS9. The reflective electrode layer RL may include at least one reflective electrode (e.g., at least one of first to fourth reflective electrodes RL1, RL2, RL3, and RL4). For example, the reflective electrode layer RL may include first to fourth reflective electrodes RL1, RL2, RL3, and RL4 as shown in FIG. 8.

Each of the first reflective electrodes RL1 may be disposed on the ninth insulating layer INS9, and may be connected to a corresponding ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first reflective electrodes RL1 may include titanium nitride (TiN).

Each of the second reflective electrodes RL2 may be disposed on a corresponding first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may include aluminum (Al).

Each of the third reflective electrodes RL3 may be disposed on a corresponding second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å. As used herein, and depending on the context, a reflective electrode may refer to a plurality of reflective electrodes located at a same layer or may refer to one reflective electrode from among the plurality of reflective electrodes located at the same layer.

The tenth insulating layer INS10 may be disposed on the ninth insulating layer INS9. The tenth insulating layer INS10 may be disposed between the reflective electrode layers RL adjacent to each other in a horizontal direction (e.g., in a direction that is substantially perpendicular to the third direction DR3). The tenth insulating layer INS10 may be disposed on the reflective electrode layer RL in the third pixel PX3. The tenth insulating layer INS10 may be formed of a silicon oxide (SiOx)-based inorganic layer, but the present disclosure is not limited thereto.

The eleventh insulating layer INS11 may be disposed on the tenth insulating layer INS10 and the reflective electrode layer RL. The eleventh insulating layer INS11 may be formed of a silicon oxide (SiOx)-based inorganic layer, but the present disclosure is not limited thereto. The tenth insulating layer INS10 and the eleventh insulating layer INS11 may be an optical auxiliary layer through which light reflected by the reflective electrode layer RL passes, among light emitted from the light emitting elements LE. For example, light emitted from the light emitting elements LE may be reflected by the reflective electrode layer RL and may pass through the tenth insulating layer INS10 and through the eleventh insulating layer INS11.

In order to match the resonance distance of the light emitted from the light emitting elements LE in at least one selected from among the first pixel PX1, the second pixel PX2, or the third pixel PX3, the tenth insulating layer INS10 and the eleventh insulating layer INS11 may not be disposed under the first electrode AND of the first pixel PX1. For example, the first electrode AND of the first pixel PX1 may be directly disposed on the reflective electrode layer RL. The eleventh insulating layer INS11 may be disposed under the first electrode AND of the second pixel PX2. The tenth insulating layer INS10 and the eleventh insulating layer INS11 may be disposed under the first electrode AND of the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the tenth insulating layer INS10 and/or the eleventh insulating layer INS11 may be set in each of the first pixel PX1, the second pixel PX2, and the third pixel PX3. For example, and referring to FIG. 8, the distance between the first electrode AND and the reflective electrode layer RL in the third pixel PX3 may be larger than (e.g., greater than) the distance between the first electrode AND and the reflective electrode layer RL in the second pixel PX2 and/or the distance between the first electrode AND and the reflective electrode layer RL in the first pixel PX1, and the distance between the first electrode AND and the reflective electrode layer RL in the second pixel PX2 may be larger than (e.g., greater than) the distance between the first electrode AND and the reflective electrode layer RL in the first pixel PX1, but the present disclosure is not limited thereto.

In one or more embodiments, a twelfth insulating layer disposed under the first electrode AND of the first pixel PX1 may be further added. In one or more embodiments, the eleventh insulating layer INS11 and a twelfth insulating layer may be disposed under the first electrode AND of the second pixel PX2, and the tenth insulating layer INS10, the eleventh insulating layer INS11, and the twelfth insulating layer may be disposed under the first electrode AND of the third pixel PX3.

Each of the tenth vias VA10 may penetrate the tenth insulating layer INS10 and/or the eleventh insulating layer INS11 in the second pixel PX2 and the third pixel PX3, and may be connected to the exposed reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the second pixel PX2 may be smaller than (e.g., less than) the thickness of the tenth via VA10 in the third pixel PX3.

The first electrode AND of each of the light emitting elements LE may be disposed on the tenth insulating layer INS10 and connected to corresponding ones of the tenth vias VA10. The first electrode AND of each of the light emitting elements LE may be connected to the drain region DA or source region SA of a corresponding pixel transistor PTR through a corresponding tenth via VA10, corresponding ones of the first to fourth reflective electrodes RL1 to RL4, corresponding ones of the the first to ninth vias VA1 to VA9, corresponding ones of the first to eighth conductive layers ML1 to ML8, and corresponding ones of the contact terminals CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light emitting elements LE may be (e.g., may include) titanium nitride (TiN).

The pixel defining layer PDL may be disposed on a part of the first electrode AND of each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first pixel PX1 to emit light. The second emission area EA2 may be defined as an area in which the first electrode AND, the light emitting stack ES, and the second electrode CAT are sequentially stacked in the second pixel PX2 to emit light. The third emission area EA3 may be defined as an area in which the first electrode AND, the light emitting stack ES, and the second electrode CAT are sequentially stacked in the third pixel PX3 to emit light.

The pixel defining layer PDL may include first to third pixel defining layers PDL1, PDL2, and PDL3. The first pixel defining layer PDL1 may be disposed on the edge of the first electrodes AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOx)-based inorganic layer, but the present disclosure is not limited thereto. The first pixel defining layer PDL1, the second pixel defining layer PDL2, and the third pixel defining layer PDL3 may each have a thickness of about 500 Å.

When the first pixel defining layer PDL1, the second pixel defining layer PDL2,

and the third pixel defining layer PDL3 are formed as one pixel defining layer, the height of the one pixel defining layer PDL increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. Furthermore, each of the plurality of trenches TRC may penetrate the eleventh insulating layer INS11. The tenth insulating layer INS10 may be partially recessed at each of the plurality of trenches TRC.

At least one trench TRC may be disposed between adjacent pixels PX1, PX2, and PX3. Although FIG. 8 illustrates that two trenches TRC are disposed between adjacent pixels PX1, PX2, and PX3, the present disclosure is not limited thereto.

The light emitting stack ES may include a plurality of stack layers. FIG. 8 illustrates that the light emitting stack ES has a three-tandem structure including a first stack layer IL1, a second stack layer IL2, and a third stack layer IL3, but the present disclosure is not limited thereto. For example, the light emitting stack ES may have a two-tandem structure including two intermediate layers.

In the three-tandem structure, the light emitting stack ES may have a tandem structure including a plurality of stack layers IL1, IL2, and IL3 that emit different lights. For example, the light emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL, and may be disposed on the bottom surface of each trench TRC. Due to the trench TRC, the first stack layer IL1 may be separated between adjacent pixels PX1, PX2, and PX3. The second stack layer IL2 may be disposed on the first stack layer IL1. Due to the trench TRC, the second stack layer IL2 may be separated between adjacent pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 may not be cut off by the trench TRC and may be disposed to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In some embodiments, for example, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be disposed on the pixel defining layer PDL.

The number of the stack layers IL1, IL2, and IL3 that emit different lights is not limited to that shown in FIG. 8. For example, the light emitting stack ES may include two intermediate layers. In this case, one of the two intermediate layers may be substantially the same as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In some embodiments, for example, FIG. 8 illustrates that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic layer TFE1 and TFE2 to prevent oxygen or moisture from permeating into the display element layer EML. For example, the encapsulation layer TFE may include the first encapsulation inorganic layer TFE1, and a second encapsulation inorganic layer TFE2.

The first encapsulation inorganic layer TFE1 may be disposed on the second electrode CAT. The first encapsulation inorganic layer TFE1 may be formed as a multilayer in which one or more inorganic layers selected from silicon nitride (SiNx), silicon oxy nitride (SiON), and silicon oxide (SiOx) are alternately stacked. The first encapsulation inorganic layer TFE1 may be formed by a chemical vapor deposition (CVD) process.

The second encapsulation inorganic layer TFE2 may be disposed on the first encapsulation inorganic layer TFE1. The second encapsulation inorganic layer TFE2 may be formed of titanium oxide (TiOx) or aluminum oxide (AlOx), but the present disclosure is not limited thereto. The second encapsulation inorganic layer TFE2 may be formed by an atomic layer deposition (ALD) process. The thickness of the second encapsulation inorganic layer TFE2 may be smaller than (e.g., less than) the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, or polyimide resin.

The optical layer OPL may include a color filter layer CFL, a lens layer, a filling layer, a cover layer, and/or a polarizing plate.

The color filter layer CFL may include the first to third color filters CF1, CF2, and CF3. The first to third color filters CF1, CF2, and CF3 may be disposed on the organic layer APL.

The first color filter CF1 may overlap the first emission area EA1 of the first pixel PX1. The first color filter CF1 may transmit light of the first color, i.e., light of a blue wavelength band. The blue wavelength band may be approximately 370 nm to 460 nm. Thus, the first color filter CF1 may transmit light of the first color among light emitted from the first emission area EA1.

The second color filter CF2 may overlap the second emission area EA2 of the second pixel PX2. The second color filter CF2 may transmit light of the second color, i.e., light of a green wavelength band. The green wavelength band may be approximately 480 nm to 560 nm. Thus, the second color filter CF2 may transmit light of the second color among light emitted from the second emission area EA2.

The third color filter CF3 may overlap the third emission area EA3 of the third pixel PX3. The third color filter CF3 may transmit light of the third color, i.e., light of a red wavelength band. The red wavelength band may be approximately 600 nm to 750 nm. Thus, the third color filter CF3 may transmit light of the third color among light emitted from the third emission area EA3.

A lens layer LSL may include a plurality of lenses LNS. The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

A filling layer FIL may be disposed on the lens layer LSL. For example, the filling layer FIL may be disposed on the plurality of lenses LNS. The filling layer FIL may have a refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for preventing visibility degradation caused by reflection of external light. The polarizing plate POL may include a linear polarizing plate and a phase retardation film. For example, the phase retardation film may be λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

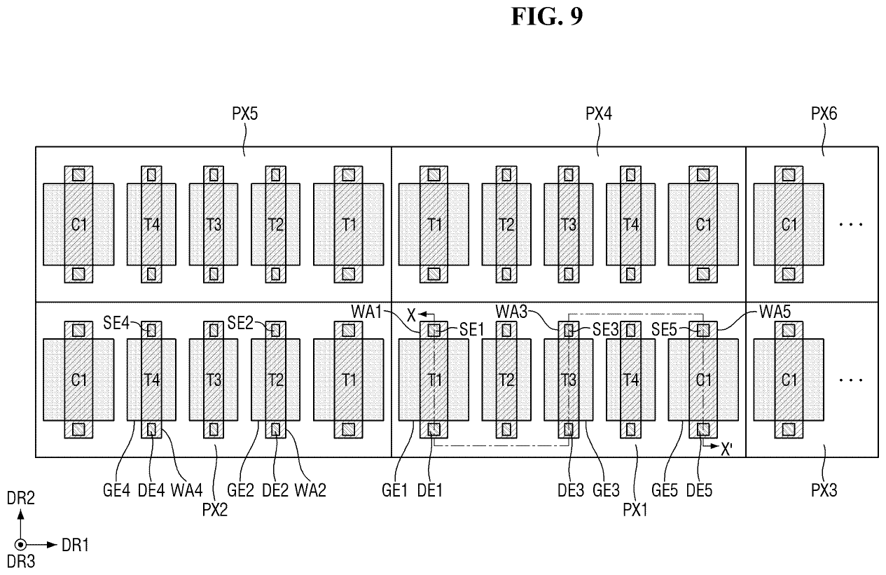

FIG. 9 is a layout diagram showing the display area of FIG. 5, according to one or more embodiments of the present disclosure.

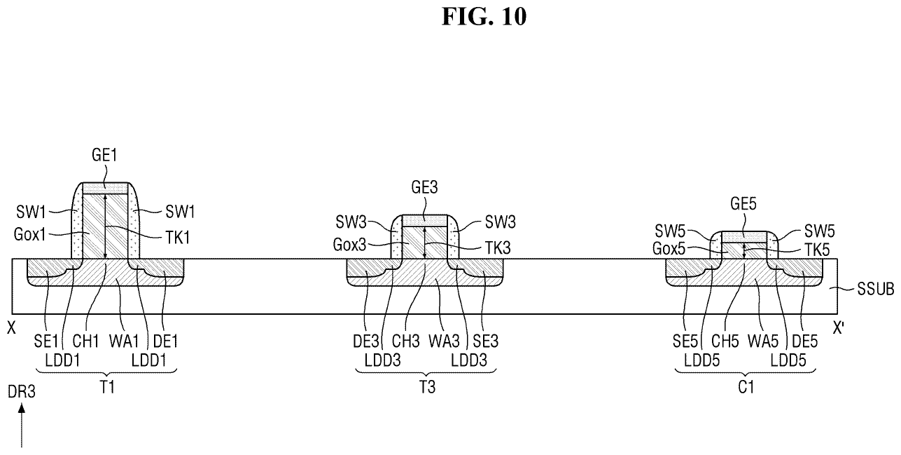

FIG. 10 is a cross-sectional view, taken along line X-X′ of FIG. 9, showing a display panel, according to one or more embodiments of the present disclosure.

Referring to FIG. 9, a plurality of pixels may be disposed in the display area DAA. For example, FIG. 9 shows six pixels, i.e., first to sixth pixels PX1, PX2, PX3, PX4, PX5, and PX6.

Each of the pixels PX1, PX2, PX3, PX4, PX5, and PX6 may include the first transistor T1, the second transistor T2, the third transistor T3, the fourth transistor T4, and the first capacitor C1 (e.g., a MOS capacitor). In one or more embodiments, although not shown, each of the pixels PX1, PX2, PX3, PX4, PX5, and PX6 may further include the second capacitor C2. In this case, the second capacitor C2 may be a MOS capacitor.

Since the components of the pixels PX1, PX2, PX3, PX4, PX5, and PX6 are substantially the same, the first pixel PX1 will be representatively described.

The first pixel PX1 may include the first transistor T1, the second transistor T2, the third transistor T3, the fourth transistor T4, and the first capacitor C1 that are disposed in a row along the first direction DR1. In one or more embodiments, when the first pixel

PX1 further includes the second capacitor C2, the second capacitor C2 may be disposed between the fourth transistor T4 and the first capacitor C1.

The first transistor T1 may include a first gate electrode GE1, a first source electrode SE1, a first drain electrode DE1, a first gate insulating layer Gox1, a first sidewall SW1, a first well region WA1, a first channel region CH1, and the first low-concentration impurity region LDD1. The first gate insulating layer Gox1 may be disposed (e.g., located or positioned) between the first channel region CH1 and the first gate electrode GE1. The first channel region CH1 may be disposed between the first source electrode SE1 and the first drain electrode DE1 in the first well region WA1. The first low-concentration impurity region LDD1 may be disposed between the first source electrode SE1 and the first channel region CH1, and between the first drain electrode DE1 and the first channel region CH1. The first sidewall SW1 may be disposed on the side surfaces of the first gate insulating layer Gox1 and the first gate electrode GE1 to overlap the first low-concentration impurity region LDD1. In this case, in plan view, the first sidewall SW1 may be disposed on the first low-concentration impurity region LDD1 to surround the side surface of the first gate insulating layer Gox1 and the side surface of the first gate electrode GE1.

The second transistor T2 (see FIG. 10) may include a second gate electrode, a second source electrode, a second drain electrode, a second gate insulating layer, a second sidewall, a second well region, a second channel region, and a second low-concentration impurity region. The second gate insulating layer may be disposed between the second channel region and the second gate electrode. The second channel region may be disposed between the second source electrode and the second drain electrode in the second well region. The second low-concentration impurity region may be disposed between the second source electrode and the second channel region, and between the second drain electrode and the second channel region. The second sidewall may be disposed on the side surfaces of the second gate insulating layer and the second gate electrode to overlap the second low-concentration impurity region. In this case, in plan view, the second sidewall may be disposed on the second low-concentration impurity region to surround the side surface of the second gate insulating layer and the side surface of the second gate electrode.

The third transistor T3 may include a third gate electrode GE3, a third source electrode SE3, a third drain electrode DE3, a third gate insulating layer Gox3, a third sidewall SW3, a third well region WA3, a third channel region CH3, and a third low-concentration impurity region LDD3. The third gate insulating layer Gox3 may be disposed between the third channel region CH3 and the third gate electrode GE3. The third channel region CH3 may be disposed between the third source electrode SE3 and the third drain electrode DE3 in the third well region WA3. The third low-concentration impurity region LDD3 may be disposed between the third source electrode SE3 and the third channel region CH3, and between the third drain electrode DE3 and the third channel region CH3. The third sidewall SW3 may be disposed on the side surfaces of the third gate insulating layer Gox3 and the third gate electrode GE3 to overlap the third low-concentration impurity region LDD3. In this case, in plan view, the third sidewall SW3 may be disposed on the third low-concentration impurity region LDD3 to surround the side surface of the third gate insulating layer Gox3 and the side surface of the third gate electrode GE3.

The fourth transistor T4 may include a fourth gate electrode, a fourth source electrode, a fourth drain electrode, a fourth gate insulating layer, a fourth sidewall, a fourth well region, a fourth channel region, and a fourth low-concentration impurity region. The fourth gate insulating layer may be disposed between the fourth channel region and the fourth gate electrode. The fourth channel region may be disposed between the fourth source electrode and the fourth drain electrode in the fourth well region. The fourth low-concentration impurity region may be disposed between the fourth source electrode and the fourth channel region, and between the fourth drain electrode and the fourth channel region. The fourth sidewall may be disposed on the side surfaces of the fourth gate insulating layer and the fourth gate electrode to overlap the fourth low-concentration impurity region. In this case, in plan view, the fourth sidewall may be disposed on the fourth low-concentration impurity region to surround the side surface of the fourth gate insulating layer and the side surface of the fourth gate electrode.

The first capacitor C1 may include a fifth gate electrode GE5, a fifth source electrode SE5, a fifth drain electrode DE5, a fifth gate insulating layer Gox5, a fifth sidewall SW5, a fifth well region WA5, a fifth channel region CH5, and a fifth low-concentration impurity region LDD5. The fifth gate insulating layer Gox5 may be disposed between the fifth channel region CH5 and the fifth gate electrode GE5. The fifth channel region CH5 may be disposed between the fifth source electrode SE5 and the fifth drain electrode DE5 in the fifth well region WA5. The fifth low-concentration impurity region LDD5 may be disposed between the fifth source electrode SE5 and the fifth channel region CH5, and between the fifth drain electrode DE5 and the fifth channel region CH5. The fifth sidewall SW5 may be disposed on the side surfaces of the fifth gate insulating layer Gox5 and the fifth gate electrode GE5 to overlap the fifth low-concentration impurity region LDD5. In this case, in plan view, the fifth sidewall SW5 may be disposed on the fifth low-concentration impurity region LDD5 to surround the side surface of the fifth gate insulating layer Gox5 and the side surface of the fifth gate electrode GE5.

In one or more embodiments, the second capacitor C2 may include a sixth gate electrode, a sixth source electrode, a sixth drain electrode, a sixth gate insulating layer, a sixth sidewall, a sixth well region, a sixth channel region, and a sixth low-concentration impurity region. The sixth gate insulating layer may be disposed between the sixth channel region and the sixth gate electrode. The sixth channel region may be disposed between the sixth source electrode and the sixth drain electrode in the sixth well region. The sixth low-concentration impurity region may be disposed between the sixth source electrode and the sixth channel region, and between the sixth drain electrode and the sixth channel region. The sixth sidewall may be disposed on the side surfaces of the sixth gate insulating layer and the sixth gate electrode to overlap the sixth low-concentration impurity region. In this case, in plan view, the sixth sidewall may be disposed on the sixth low-concentration impurity region to surround the side surface of the sixth gate insulating layer and the side surface of the sixth gate electrode.

In accordance with one or more embodiments, the body electrode of each of the first to fourth transistors T1-T4, the first capacitor C1, and the second capacitor C2 may be disposed in the body well region on the semiconductor substrate SSUB. In other words, the body electrode may be disposed in a separate well region similarly to the source electrode or drain electrode of each transistor described above.

In accordance with one or more embodiments, the thicknesses of the gate insulating layers of at least two transistors may be different from each other. For example, as in the example shown in FIG. 10, a thickness TK1 (hereinafter, referred to as first thickness) of the first gate insulating layer Gox1 provided in the first transistor T1 may be larger than (e.g., greater than) a thickness TK3 (hereinafter, referred to as third thickness) of the third gate insulating layer Gox3 provided in the third transistor T3, and the thickness TK3 of the third gate insulating layer Gox3 provided in the third transistor T3 may be larger than (e.g., greater than) a thickness TK5 (hereinafter, referred to as fifth thickness) of the fifth gate insulating layer Gox5 provided in the first capacitor C1. For example, the third thickness TK3 may be larger than (e.g., greater than) the fifth thickness TK5 and smaller than (e.g., less than) the first thickness TK1.

In accordance with one or more embodiments, each of the thickness of the

second gate insulating layer of the second transistor T2 and the thickness of the fourth gate insulating layer of the fourth transistor T4 may be substantially the same as (e.g., substantially equal to) the third thickness TK3 described above. For example, the thicknesses of the gate insulating layers of the other transistors (e.g., the second to fourth transistors T2 to T4) except the first transistor T1 that is a driving transistor may be the same. In other words, among the first to fourth transistors T1 to T4, the first transistor T1 that is a driving transistor may include the gate insulating layer having the largest thickness TK1 (e.g., the largest thickness from among the gate insulating layers of the first to fourth transistors T1 to T4).

In accordance with one or more embodiments, the thickness of the sixth gate insulating layer provided in the second capacitor C2 may be substantially the same as (e.g., substantially equal to) the thickness of the fifth gate insulating layer Gox5 provided in the first capacitor C1. In one or more embodiments, the thickness of the sixth gate insulating layer may be larger than (e.g., greater than) the thickness TK5 of the fifth gate insulating layer Gox5 and smaller than (e.g., less than) the thickness of the gate insulating layer provided in any one of the second to fourth transistors T2 to T4. For example, the thickness of the sixth gate insulating layer may be larger than (e.g., greater than) the thickness TK5 of the fifth gate insulating layer Gox5, and may be smaller than (e.g., less than) the thickness TK3 of the third gate insulating layer.

Since the first transistor T1 that is a driving transistor includes the relatively

thick first gate insulating layer Gox1, the distance between the first gate electrode GE1 and the first channel region CH1 may increase. Hence, the channel resistance of the first transistor T1 may increase, so that the characteristic curve representing a ratio of a drain current according to the gate-source voltage of the first transistor T1 may have a gentle slope (e.g., a more gradual slope). Therefore, the operating range in the linear region of the first transistor T1 may increase, thereby allowing fine grayscale expression of the display device. For example, increasing a thickness of first gate insulating layer Gox1 may allow the display device to display grayscale values more finely than with a thinner first gate insulating layer Gox1.

In one or more embodiments, the third transistor T3 that is a switching transistor includes the third gate insulating layer Gox3 having a thickness larger than (e.g., greater than) that of the fifth gate insulating layer Gox5 and smaller than (e.g., less than) that of the first gate insulating layer Gox1, so that the distance between the third gate electrode GE3 and the third channel region CH3 may be smaller than (e.g., less than) the distance between the first channel region CH1 and the first gate electrode GE1 of the first transistor T1. Hence, the channel resistance of the third transistor T3 may decrease, so that the characteristic curve representing a ratio of a drain current according to the gate-source voltage of the third transistor T3 may have a steep slope. Therefore, the on/off switching capability of the third transistor T3 may be improved. Other switching transistors, such as the second transistor T2 and the fourth transistor T4, may also have improved on/off switching capability for the same reason as that of the third transistor T3 described above.

Further, since the first capacitor C1 includes the relatively thin fifth gate

insulating layer Gox5, the distance between the fifth gate electrode GE5 and the fifth channel region CH5 (or the distance between the fifth gate electrode GE5 and the semiconductor substrate SSUB) is shortened and, thus, the capacitance of the first capacitor C1 may be increased.

In accordance with one or more embodiments, transistors and capacitors of adjacent pixels may be symmetrically disposed so that the first transistors T1 of the adjacent pixels are adjacent to each other. For example, as shown in FIG. 9, the first pixel PX1 may include the first transistor T1, the second transistor T2, the third transistor T3, the fourth transistor T4, and the first capacitor C1 that are sequentially disposed along the first direction DR1, and the second pixel PX2 adjacent to the first pixel PX1 in the reverse direction (hereinafter, referred to as first reverse direction) of the first direction DR1 may include the first transistor T1, the second transistor T2, the third transistor T3, the fourth transistor T4, and the first capacitor C1 that are sequentially disposed along the first reverse direction. Accordingly, the first transistor T1 of the first pixel PX1 and the first transistor T1 of the second pixel PX2 may be adjacent to each other in the first direction DR1.

For another example, as shown in FIG. 9, the first pixel PX1 may include the first transistor T1, the second transistor T2, the third transistor T3, the fourth transistor

T4, and the first capacitor C1 that are sequentially disposed along the first direction DR1, and the third pixel PX3 adjacent to the first pixel PX1 in the first direction DR1 may include the first transistor T1, the second transistor T2, the third transistor T3, the fourth transistor T4, and the first capacitor C1 that are sequentially disposed along the first reverse direction. Accordingly, the first capacitor C1 of the first pixel PX1 and the first capacitor C1 of the third pixel PX3 may be adjacent to each other in the first direction DR1.

In accordance with one or more embodiments, the first capacitor C1 and the first transistor T1 that is a driving transistor in one pixel may be disposed to be located farthest from each other. For example, the first transistor T1 may be disposed at one edge of the first pixel PX1, and the first capacitor C1 may be disposed at another edge (e.g., the other or opposite edge) of the first pixel PX1 so that the first transistor T1 and the first capacitor C1 of the first pixel PX1 are located farthest from each other in the first direction DR1.

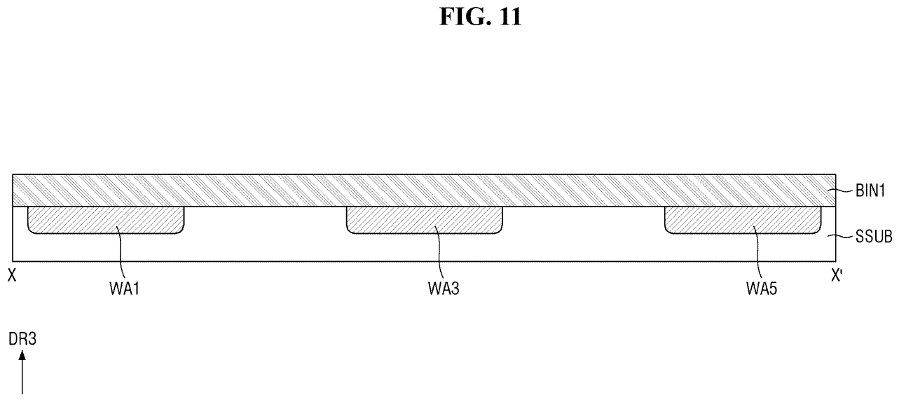

FIGS. 11 to 23 are process cross-sectional views illustrating a method for

fabricating a display device according to one or more embodiments.

As shown in FIG. 11, the first well region WA1, the third well region WA3, and the fifth well region WA5 may be formed on the semiconductor substrate SSUB. Here, the semiconductor substrate may be, e.g., a P-type semiconductor substrate SSUB, and each of the first well region WA1, the third well region WA3, and the fifth well region WA5 may be an N-type well region. Thereafter, as shown in FIG. 11, a first base insulating layer BIN1 may be disposed on (e.g., over) the semiconductor substrate SSUB including the well regions. The first base insulating layer BIN1 may be made of SiOx.

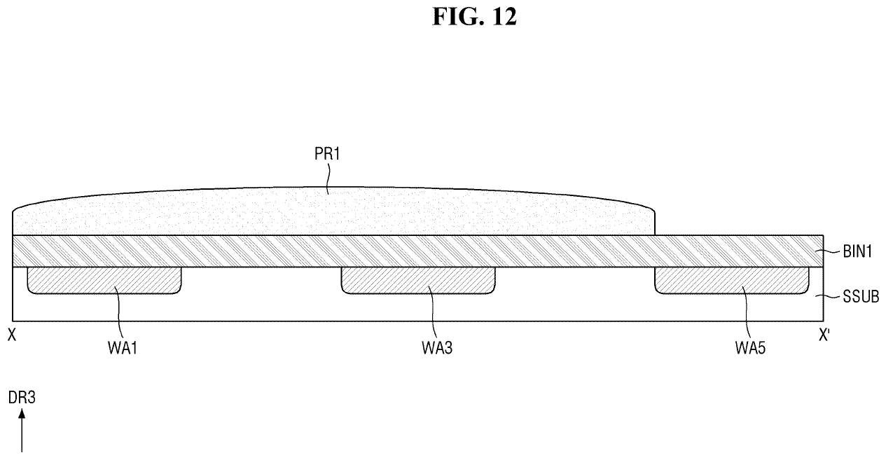

Next, as shown in FIG. 12, a first photoresist pattern PR1 may be disposed on the first base insulating layer BIN1. The first photoresist pattern PR1 may be disposed on the first base insulating layer BIN1 to cover (or overlap) the other well regions except the fifth well region WA5.

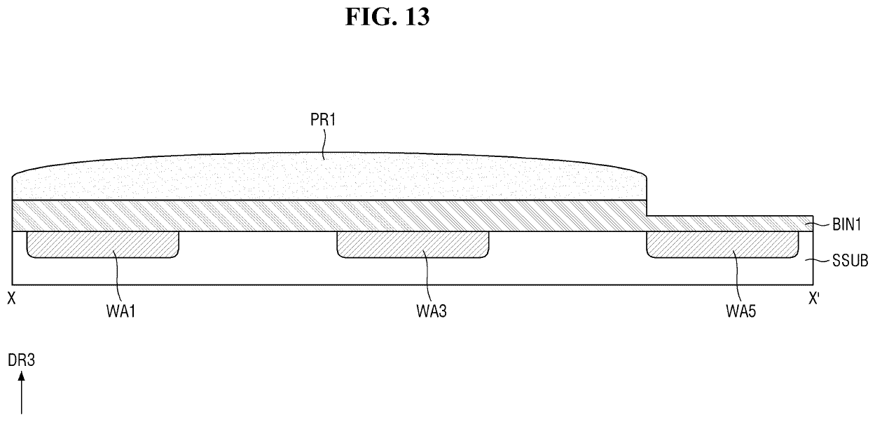

Thereafter, as shown in FIG. 13, the first base insulating layer BIN1 may be selectively removed using the first photoresist pattern PR1 as a mask. For example, the first base insulating layer BIN1 may be partially removed from a region (e.g., the fifth well region WA5) that is not covered by the first photoresist pattern PR1. In other words, a part of the first base insulating layer BIN1 on the fifth well region WA5 may be removed. Accordingly, the first base insulating layer BIN1 may be patterned to have a smaller thickness in the fifth well region WA5 than in the first well region WA1 and the third well region WA3. In accordance with one or more embodiments, the first base insulating layer BIN1 may be removed by an etching (e.g., a dry etching) method.

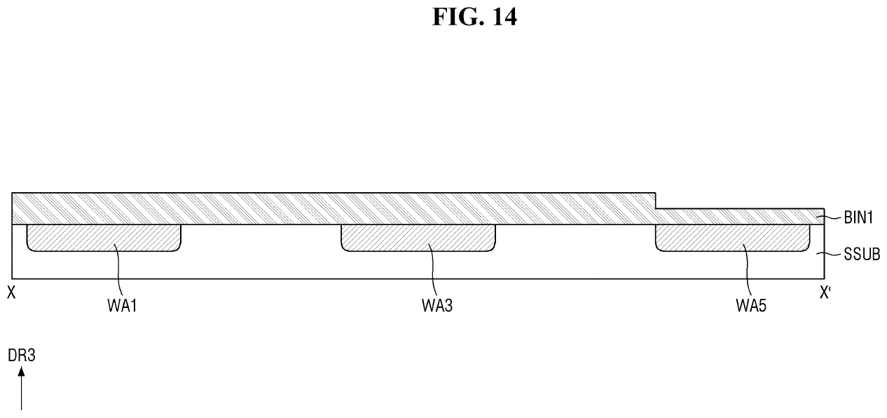

Next, as shown in FIG. 14, the first photoresist pattern PR1 on the patterned first base insulating layer BIN1 may be removed. The first photoresist pattern PR1 may be removed by a strip solution.

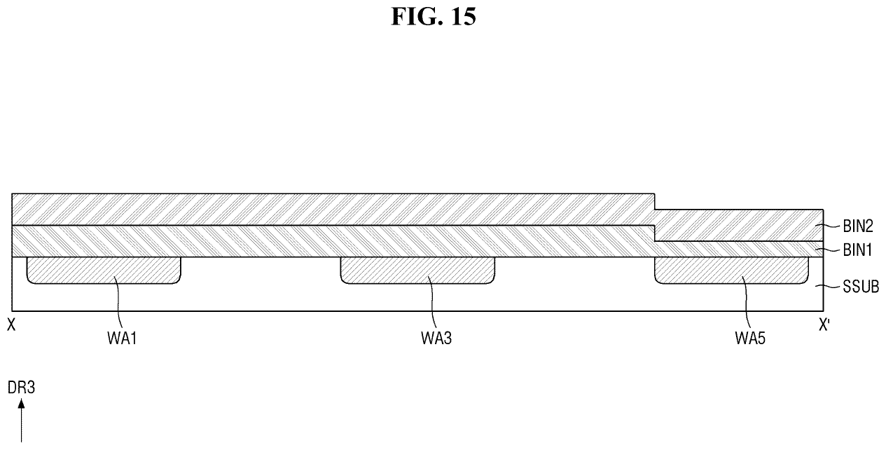

Thereafter, as shown in FIG. 15, a second base insulating layer BIN2 may be formed on the patterned first base insulating layer BIN1. The second base insulating layer BIN2 may be formed on the entire surface of the semiconductor substrate including the first base insulating layer BIN1. In this case, since the patterned first base insulating layer BIN1 has a small thickness in the fifth well region WA5, the second base insulating layer BIN2 on the first base insulating layer BIN1 may also have a small thickness in the fifth well region WA5. The second base insulating layer BIN2 may be made of SiOx.

In accordance with one or more embodiments, the second base insulating layer BIN2 may include the same material as that of the first base insulating layer BIN1. However, the present disclosure is not limited thereto, and the second base insulating layer BIN2 and the first base insulating layer BIN1 may include different materials so that the second base insulating layer BIN2 and the first base insulating layer BIN1 have different etching ratios.

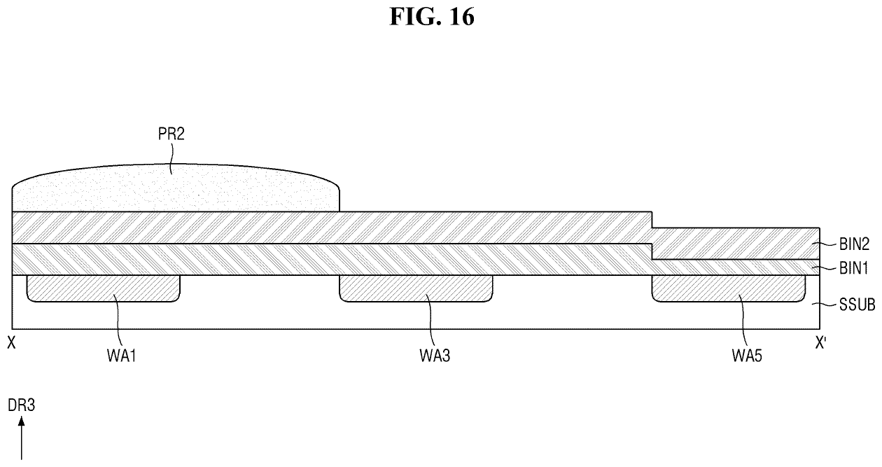

Next, as shown in FIG. 16, a second photoresist pattern PR2 may be disposed on the second base insulating layer BIN2. The second photoresist pattern PR2 may be disposed on the second base insulating layer BIN2 to cover (or overlap) the other well regions (e.g., the first well region WA1) except the third well region WA3 and the fifth well region WA5.

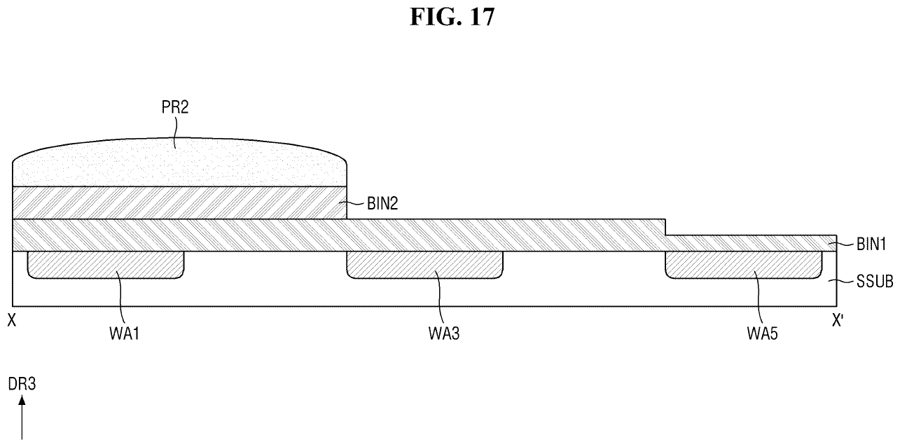

Thereafter, as shown in FIG. 17, the second base insulating layer BIN2 may be selectively removed using the second photoresist pattern PR2 as a mask. For example, the second base insulating layer BIN2 may be removed from the region (e.g., the third well region WA3 and the fifth well region WA5) that is not covered by the second photoresist pattern PR2. In other words, the second base insulating layer BIN2 on the third well region WA3 and the fifth well region WA5 may be removed. Accordingly, the second base insulating layer BIN2 may be patterned to be selectively disposed only on the first well region WA1. In accordance with one or more embodiments, the second base insulating layer BIN2 may be removed by an etching (e.g., a dry etching) method.

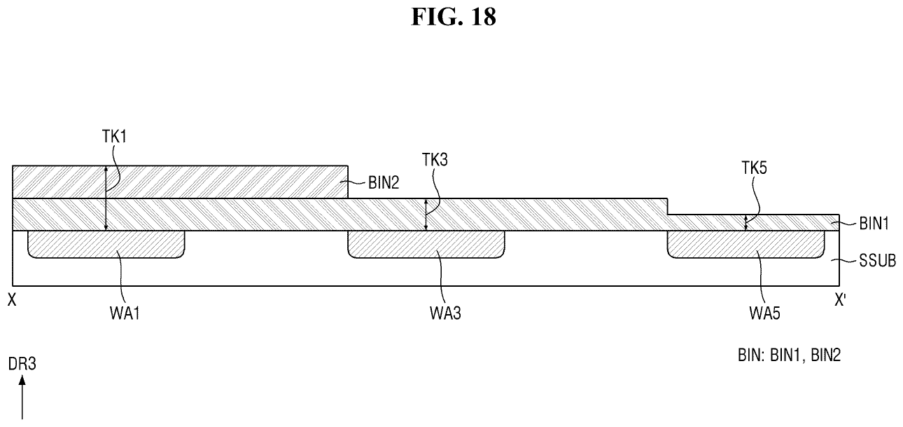

Next, as shown in FIG. 18, the second photoresist pattern PR2 on the patterned second base insulating layer BIN2 may be removed. The second photoresist pattern PR2 may be removed by a strip solution. Accordingly, the base insulating layer BIN having the first thickness TK1, the third thickness TK3, and the fifth thickness TK5 that are different from each other may be formed. For example, the base insulating layer BIN having the first thickness TK1 that is the largest in the first well region WA1, the third thickness TK3 smaller than (e.g., less than) the first thickness TK1 in the third well region WA3, and the fifth thickness TK5 that is the smallest in the fifth well region WA5 may be formed. Here, when the first base insulating layer BIN1 and the second base insulating layer BIN2 are made of different materials, the base insulating layer BIN may have an interface between the first base insulating layer BIN1 and the second base insulating layer BIN2. In one or more embodiments, when the first base insulating layer BIN1 and the second base insulating layer BIN2 are made of the same material, the first base insulating layer BIN1 and the second base insulating layer BIN2 may be integrally formed without an interface.

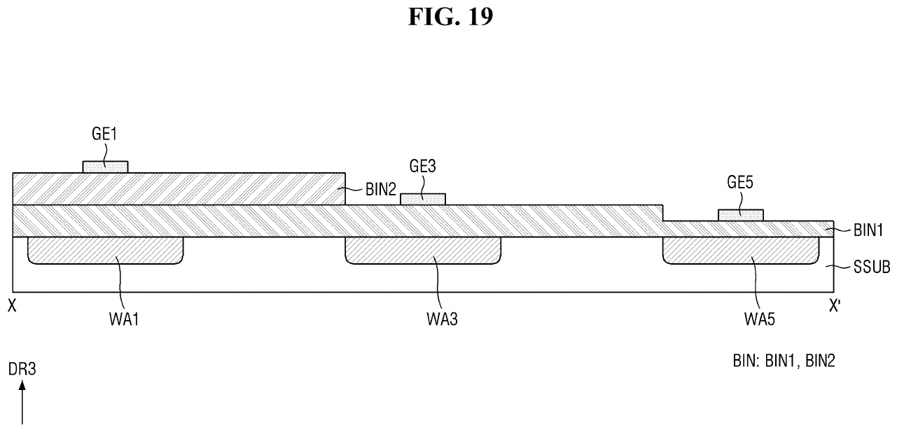

Next, as shown in FIG. 19, the first gate electrode GE1 may be disposed on the base insulating layer BIN (e.g., the second base insulating layer BIN2) to overlap the first well region WA1, the third gate electrode GE3 may be disposed on the base insulating layer BIN (e.g., the first base insulating layer BIN1) to overlap the third well region WA3, and the fifth gate electrode GE5 may be disposed on the base insulating layer BIN (e.g., the first base insulating layer BIN1) to overlap the fifth well region WA5. In accordance with one or more embodiments, each of the first gate electrode GE1, the third gate electrode GE3, and the fifth gate electrode GE5 may be made of polysilicon.

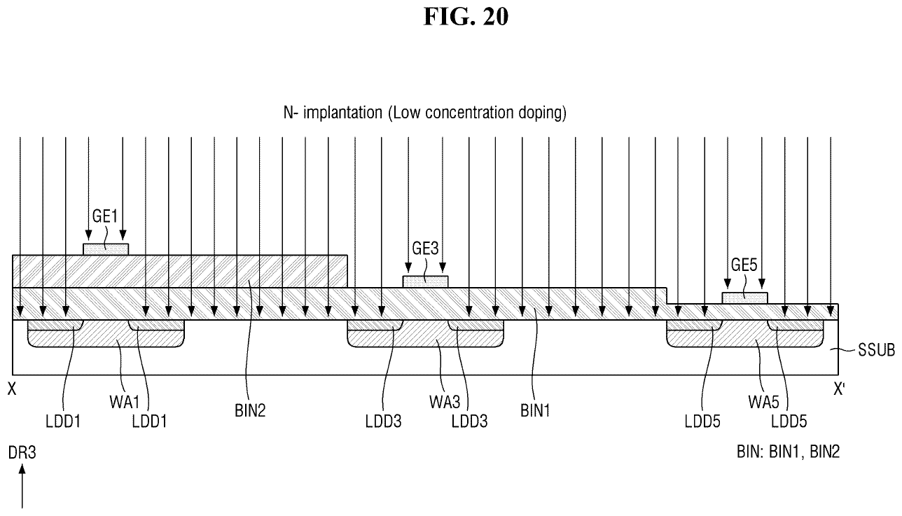

Thereafter, as shown in FIG. 20, a low-concentration ion (e.g., N-) implantation process may be performed using the first gate electrode GE1, the third gate electrode GE3, and the fifth gate electrode GE5 as a mask (e.g., a hard mask). Due to the low-concentration ion implantation process, the first low-concentration impurity region LDD1 may be formed in the first well region WA1, the third low-concentration impurity region LDD3 may be formed in the third well region WA3, and the fifth low-concentration impurity region LDD5 may be formed in the fifth well region WA5.

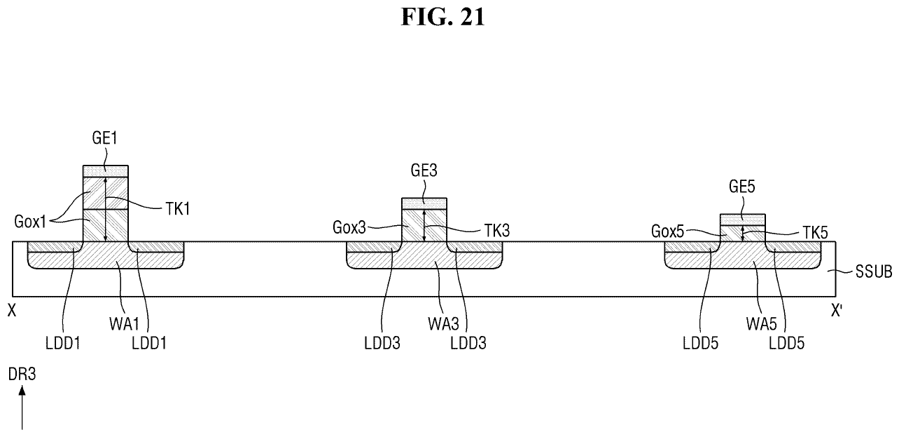

Next, as shown in FIG. 21, the base insulating layer BIN may be selectively removed using the first gate electrode GE1, the third gate electrode GE3, and the fifth gate electrode GE5 as a mask. Accordingly, the first gate insulating layer Gox1 having the first thickness TK1 may be formed between the first gate electrode GE1 and the first well region WA1, the third gate insulating layer Gox3 having the third thickness TK3 may be formed between the third gate electrode GE3 and the third well region WA3, and the fifth gate insulating layer Gox5 having the fifth thickness TK5 may be formed between the fifth gate electrode GE5 and the fifth well region WA5. In accordance with one or more embodiments, when the first base insulating layer BIN1 and the second base insulating layer BIN2 are made of different materials, the fifth gate insulating layer Gox5 may include a first sub-gate insulating layer formed of the first base insulating layer BIN1 and a second sub-gate insulating layer formed of the second base insulating layer BIN2, and an interface may exist between the first sub-gate insulating layer and the second sub-gate insulating layer. In one or more embodiments, when the first base insulating layer BIN1 and the second base insulating layer BIN2 are made of the same material, the fifth gate insulating layer Gox5 may be formed of the base insulating layer BIN that does not include an interface (e.g., see FIG. 10).

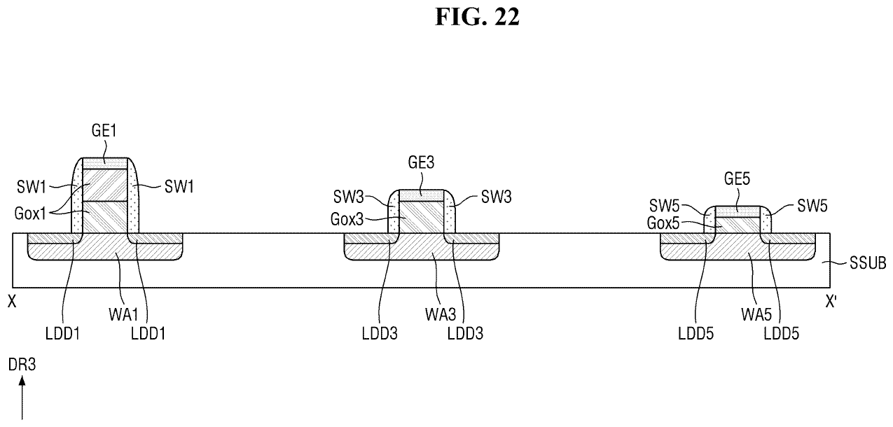

Next, as shown in FIG. 22, the first sidewall SW1 may be formed on the side surfaces of the first gate insulating layer Gox1 and the first gate electrode GE1 to overlap the first low-concentration impurity region LDD1, the third sidewall SW3 may be formed on the side surfaces of the third gate insulating layer Gox3 and the third gate electrode GE3 to overlap the third low-concentration impurity region LDD3, and the fifth sidewall SW5 may be formed on the side surfaces of the fifth gate insulating layer Gox5 and the fifth gate electrode GE5 to overlap the fifth low-concentration impurity region LDD5.

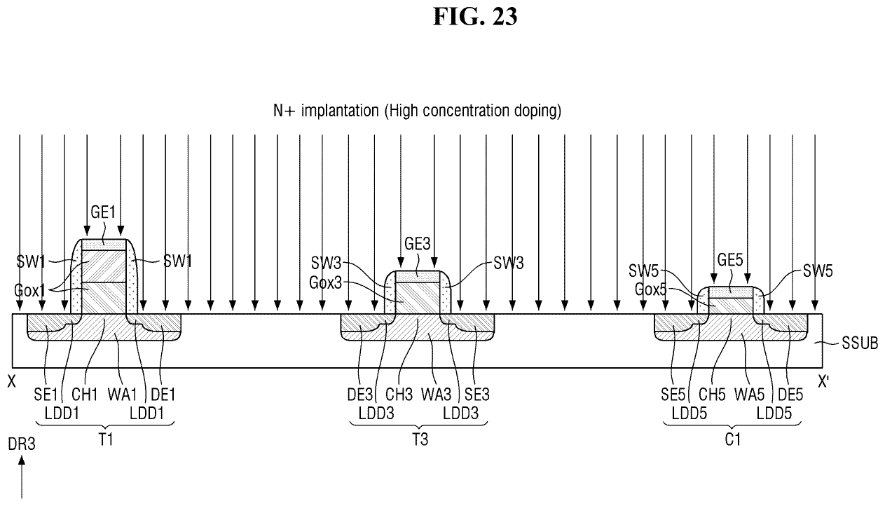

Next, as shown in FIG. 23, a high-concentration ion (e.g., N+) implantation process may be performed using the first gate electrode GE1, the first sidewall SW1, the third gate electrode GE3, the third sidewall SW3, the fifth gate electrode GE5, and the fifth sidewall SW5 as a mask. Due to the high-concentration ion implantation process, the first source electrode SE1 and the first drain electrode DE1 may be formed in areas of the first low-concentration impurity region LDD1 that are not covered by the first sidewall SW1, the third source electrode SE3 and the third drain electrode DE3 may be formed in areas of the third low-concentration impurity region LDD3 that are not covered by the third sidewall SW3, and the fifth source electrode SE5 and the fifth drain electrode DE5 may be formed in areas of the fifth low-concentration impurity region LDD5 that are not covered by the fifth sidewall SW5. For example, the exposed area in the low-concentration impurity region may be converted to the high-concentration impurity region by counter doping using high-concentration ion implantation. Accordingly, the first transistor T1, the third transistor T3, and the first capacitor C1 may be fabricated.

In one or more embodiments, the second transistor T2 and the fourth transistor T4 may be fabricated by the same method as that of the third transistor T3 described above, and the second capacitor C2 may be fabricated by the same method as that of the first capacitor C1 described above. In this case, the first transistor T1, the second transistor T2, the third transistor T3, the fourth transistor T4, the first capacitor C1, and the second capacitor C2 may be fabricated substantially simultaneously by the processes shown in FIGS. 11 to 23 described above.

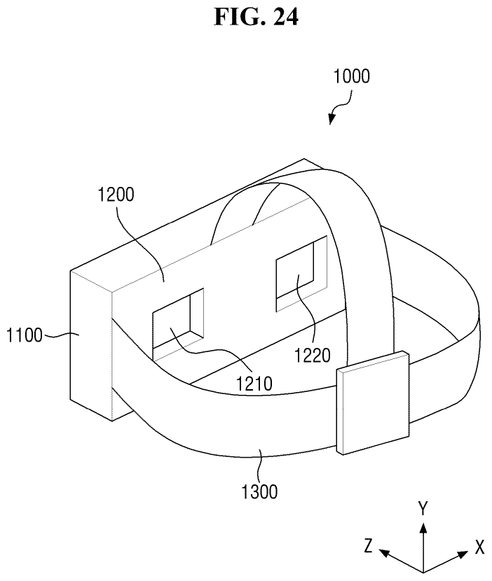

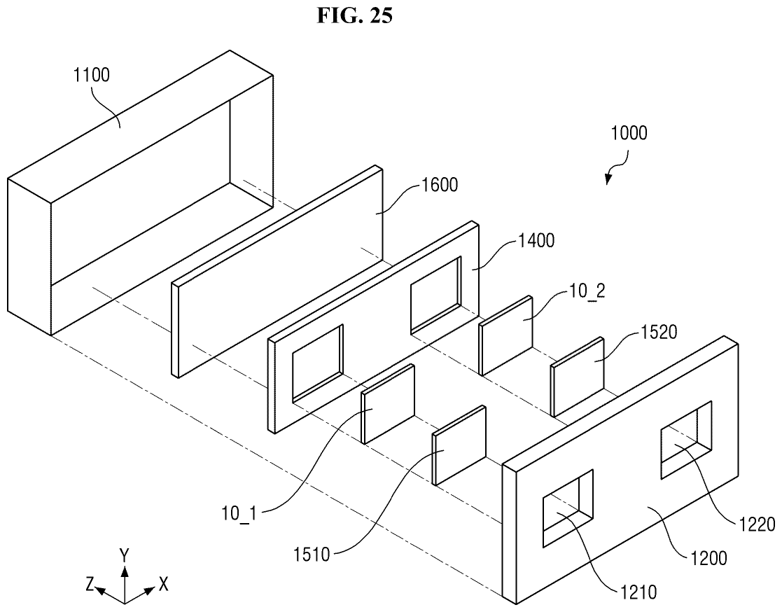

FIG. 24 is a perspective view illustrating a head mounted display, according to one or more embodiments of the present disclosure. FIG. 25 is an exploded perspective view illustrating the head mounted display of FIG. 24, according to one or more embodiments of the present disclosure.

Referring to FIGS. 24 and 25, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 and 2, a description of the first display device 10_1 and the second display device 10_2 is omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA

corresponding to a left-eye image optimized for the user's left eye to the first display device 10_1, and may transmit the digital video data DATA corresponding to a right-eye image optimized for the user's right eye to the second display device 10_2. In one or more embodiments, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 24 and 25 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

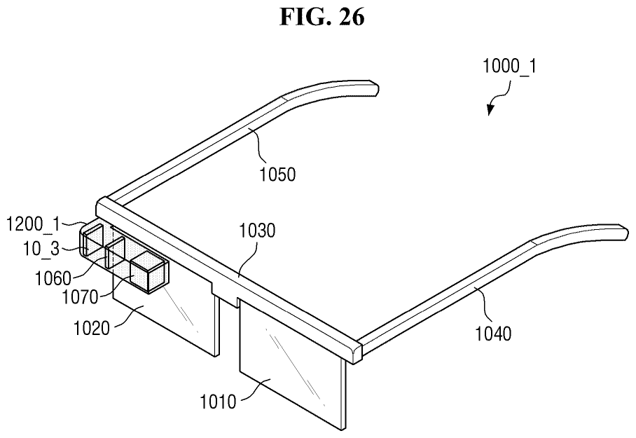

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1200 is implemented to be lightweight and compact, the head mounted display 1000 may be provided with, as shown in FIG. 26, an eyeglass frame instead of the head mounted band 1300.

In some embodiments, for example, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 26 is a perspective view illustrating a head mounted display, according to one or more embodiments of the present disclosure.

Referring to FIG. 26, a head mounted display 1000_1 according to one or more embodiments may be an eyeglasses-type display device in which a display device housing 1200_1 is implemented in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 26 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. In one or more embodiments, the display device housing 1200_1 may be disposed at both the left and right ends of the support frame 1030, and in this case, the user may view the image displayed on the display device 10_3 through both the left and right eyes.

Although some embodiments have been described, those skilled in the art will

readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various aspects of example embodiments and is not to be construed as limited to the specific embodiments disclosed herein, and that various modifications to the disclosed embodiments, as well as other aspects of example embodiments, are intended to be included within the spirit and scope of the present disclosure as defined in the appended claims, and their equivalents.

What is claimed is:

1. A display device comprising:
a substrate comprising a first well region, a third well region, and a fifth well region;
a first source electrode and a first drain electrode in the first well region;
a third source electrode and a third drain electrode in the third well region;
a fifth source electrode and a fifth drain electrode in the fifth well region;
a first gate electrode on a first channel region of the first well region;
a third gate electrode on a third channel region of the third well region;
a fifth gate electrode on a fifth channel region of the fifth well region;
a first gate insulating layer between the first channel region and the first gate electrode;
a third gate insulating layer between the third channel region and the third gate electrode;
a fifth gate insulating layer between the fifth channel region and the fifth gate electrode;
a first electrode connected to the first drain electrode;
a light emitting layer on the first electrode; and
a second electrode on the light emitting layer,
wherein at least two of the first gate insulating layer, the third gate insulating layer, or the fifth gate insulating layer have thicknesses that are different from each other.

2. The display device of claim 1, wherein a thickness of the third gate insulating layer is greater than a thickness of the fifth gate insulating layer and less than a thickness of the first gate insulating layer.

3. The display device of claim 2, further comprising:
a first transistor comprising the first gate electrode, the first source electrode, the first drain electrode, and the first gate insulating layer;
a third transistor comprising the third gate electrode, the third source electrode, the third drain electrode, and the third gate insulating layer; and
a first capacitor comprising the fifth gate electrode, the fifth source electrode, the fifth drain electrode, and the fifth gate insulating layer.

4. The display device of claim 3, wherein the third transistor is connected between a driving voltage line and the first source electrode of the first transistor.

5. The display device of claim 3, further comprising a second transistor connected between a data line and the first gate electrode of the first transistor.

6. The display device of claim 5, wherein the second transistor comprises:
a second source electrode and a second drain electrode in a second well region of the substrate;
a second gate electrode on a second channel region of the second well region; and
a second gate insulating layer between the second channel region and the second gate electrode.

7. The display device of claim 6, wherein a thickness of the second gate insulating layer is equal to the thickness of the third gate insulating layer.

8. The display device of claim 3, further comprising a fourth transistor connected between an initialization voltage line and the first drain electrode of the first transistor.

9. The display device of claim 8, wherein the fourth transistor comprises:
a fourth source electrode and a fourth drain electrode in a fourth well region of the substrate;
a fourth gate electrode on a fourth channel region of the fourth well region; and
a fourth gate insulating layer between the fourth channel region and the fourth gate electrode.

10. The display device of claim 9, wherein a thickness of the fourth gate insulating layer is equal to the thickness of the third gate insulating layer.

11. The display device of claim 3, further comprising a second capacitor connected between the first gate electrode of the first transistor and the first source electrode of the first transistor.

12. The display device of claim 11, wherein the second capacitor comprises:
a sixth source electrode and a sixth drain electrode in a sixth well region of the substrate;
a sixth gate electrode on a sixth channel region of the sixth well region; and
a sixth gate insulating layer between the sixth channel region and the sixth gate electrode.

13. The display device of claim 12, wherein a thickness of the sixth gate insulating layer is equal to the thickness of the fifth gate insulating layer.

14. The display device of claim 12, wherein a thickness of the sixth gate insulating layer is greater than the thickness of the fifth gate insulating layer.

15. The display device of claim 14, wherein the thickness of the sixth gate insulating layer is greater than the thickness of the third gate insulating layer.

16. The display device of claim 3, wherein in a first pixel and a second pixel adjacent to each other,
the first transistor of the first pixel and the first transistor of the second pixel are adjacent to each other.

17. The display device of claim 3, wherein in a first pixel and a second pixel adjacent to each other,
the first capacitor of the first pixel and the first capacitor of the second pixel are adjacent to each other.

18. The display device of claim 3, wherein the first transistor is located at one edge of a pixel, and the first capacitor is located at another edge of the pixel.

19. A method for fabricating a display device, comprising:
forming a first well region, a third well region, and a fifth well region on a substrate;
forming a first base insulating layer on a surface of the substrate comprising the first well region, the third well region, and the fifth well region;
forming a first photoresist pattern on the first base insulating layer to cover the first well region and the third well region;
selectively removing the first base insulating layer using the first photoresist pattern as a mask to form a first base insulating layer having a thickness in the fifth well region that is less than a thickness of the first base insulating layer in the first well region and the third well region;
removing the first photoresist pattern;
forming a second base insulating layer on the first base insulating layer;
forming a second photoresist pattern on the second base insulating layer to cover the first well region; and
selectively removing the second base insulating layer using the second photoresist pattern as a mask to form a base insulating layer having a first thickness in the first well region, a third thickness in the third well region, and a fifth thickness in the fifth well region, the first thickness being greater than the third thickness, and the third thickness being greater than the fifth thickness.

20. The method of claim 19, further comprising:
removing the second photoresist pattern;
forming a first gate electrode on the base insulating layer to overlap with the first well region, forming a third gate electrode on the base insulating layer to overlap with the third well region, and disposing a fifth gate electrode on the base insulating layer to overlap with the fifth well region; and
performing an ion implantation process using the first gate electrode, the third gate electrode, and the fifth gate electrode as a mask to form a first low-concentration impurity region in the first well region, to form a third low-concentration impurity region in the third well region, and to form a fifth low-concentration impurity region in the fifth well region.

21. The method of claim 20, further comprising:
selectively removing the base insulating layer using the first gate electrode, the third gate electrode, and the fifth gate electrode as a mask to form a first gate insulating layer having a first thickness between the first gate electrode and the first well region, to form a third gate insulating layer having a third thickness between the third gate electrode and the third well region, and to form a fifth gate insulating layer having a fifth thickness between the fifth gate electrode and the fifth well region.

22. The method of claim 21, further comprising:
forming a first sidewall on side surfaces of the first gate insulating layer and the first gate electrode to overlap with the first low-concentration impurity region, forming a third sidewall on side surfaces of the third gate insulating layer and the third gate electrode to overlap with the third low-concentration impurity region, and forming a fifth sidewall on side surfaces of the fifth gate insulating layer and the fifth gate electrode to overlap with the fifth low-concentration impurity region; and
performing a high-concentration ion implantation process using the first gate electrode, the first sidewall, the third gate electrode, the third sidewall, the fifth gate electrode, and the fifth sidewall as a mask to form a first source electrode and a first drain electrode in a part of the first low-concentration impurity region, to form a third source electrode and a third drain electrode in a part of the third low-concentration impurity region, and to form a fifth source electrode and a fifth drain electrode in a part of the fifth low-concentration impurity region.
